(19) United States
(12) Patent Application Publication
(10) Pub. No.: US 2026/0023495 A1
(43) Pub. Date: Jan. 22, 2026

(54) HIGHEST DATA STATE PROGRAM-VERIFY SKIP FOR PROGRAM PERFORMANCE IMPROVEMENT

(71) Applicant: Sandisk Technologies, Inc., Milpitas, CA (US)

(72) Inventors: Hua-Ling Cynthia Hsu, Fremont, CA (US); Henry Chin, Fremont, CA (US); Chengqing Hu, Milpitas, CA (US)

(21) Appl. No.: 18/776,354

(22) Filed: Jul. 18, 2024

(51) Int. Cl. G06F 3/06

(52) U.S. Cl. CPC G06F 3/0644; G06F 3/0604; G06F 3/0679

(57) ABSTRACT

A memory apparatus and operating method are provided. The apparatus includes memory cells connected to word lines and configured to retain a threshold voltage corresponding to data states. The data states includes a highest data state in which the threshold voltage of the memory cells associated therewith is higher than for others of the data states. A control means is configured to apply each of a series of programming pulses of a program voltage followed by verification pulses of a plurality of program verify voltages each associated with one of the data states to selected ones of the word lines to program and verify the memory cells connected thereto during each of a plurality of program loops of a program operation. The control means skips verification of the memory cells targeted for the highest data state in at least one of the plurality of program loops.

### FIELD

The present technology relates to the operation of memory devices.

### BACKGROUND

Semiconductor memory devices or apparatuses are widely used in various electronic devices such as laptops, digital audio players, digital cameras, cellular phones, video game consoles, scientific instruments, industrial robots, medical electronics, solid state drives, automotive electronics, Internet of Things (IoT) devices and universal serial bus (USB) devices. Semiconductor memory includes both non-volatile and volatile memory. Non-volatile memory retains stored information without requiring an external power source. Examples of non-volatile memory include flash memory (e.g., NAND-type and NOR-type flash memory) and Electrically Erasable Programmable Read-Only Memory (EEPROM).

A memory apparatus can be coupled to one or more hosts, where one or more interfaces are used to access the memory apparatus. Additionally, the memory apparatus is often managed by a controller, where among several roles, the controller is configured to interface between the host and the memory apparatus.

To improve performance, some memory apparatuses utilize various techniques to limit verify iterations for certain data states during programming. However, while such techniques can provide reduced program time, some adverse effects may result. Thus, there is a need for improved non-volatile memory apparatuses and methods of operation.

### SUMMARY

This section provides a general summary of the present disclosure and is not a comprehensive disclosure of its full scope or all of its features and advantages.

An object of the present disclosure is to provide a memory apparatus and a method of operating the memory apparatus that address and overcome the shortcomings described herein.

Accordingly, it is an aspect of the present disclosure to provide a memory apparatus including memory cells each connected to one of a plurality of word lines and configured to retain a threshold voltage corresponding to one of a plurality of data states. The plurality of data states includes a highest data state in which the threshold voltage of the memory cells associated therewith is higher than for others of the plurality of data states. The memory apparatus also includes a control means configured to apply each of a series of programming pulses of a program voltage followed by verification pulses of a plurality of program verify voltages each associated with one of the plurality of data states to selected ones of the plurality of word lines. Thus, the memory cells connected to the selected pones of the plurality of word lines are programmed and verified during each of a plurality of program loops of a program operation. The control means is also configured to skip verification of the memory cells targeted for the highest data state in at least one of the plurality of program loops.

According to another aspect of the disclosure, a controller in communication with a memory apparatus including memory cells each connected to one of a plurality of word lines is also provided. The memory cells are configured to retain a threshold voltage corresponding to one of a plurality of data states. The plurality of data states includes a highest data state in which the threshold voltage of the memory cells associated therewith is higher than for others of the plurality of data states. The controller is configured to instruct the memory apparatus to apply each of a series of programming pulses of a program voltage followed by verification pulses of a plurality of program verify voltages each associated with one of the plurality of data states to selected ones of the plurality of word lines. Therefore, the memory cells connected to the selected pones of the plurality of word lines are programmed and verified during each of a plurality of program loops of a program operation. The controller is also configured to instruct the memory apparatus to skip verification of the memory cells targeted for the highest data state in at least one of the plurality of program loops.

According to an additional aspect of the disclosure, a method of operating a memory apparatus is provided. The memory apparatus includes memory cells each connected to one of a plurality of word lines. The memory cells are configured to retain a threshold voltage corresponding to one of a plurality of data states. The plurality of data states includes a highest data state in which the threshold voltage of the memory cells associated therewith is higher than for others of the plurality of data states. The method includes the step of applying each of a series of programming pulses of a program voltage followed by verification pulses of a plurality of program verify voltages each associated with one of the plurality of data states to selected ones of the plurality of word lines to program and verify the memory cells connected thereto during each of a plurality of program loops of a program operation. The method also includes the step of skipping verification of the memory cells targeted for the highest data state in at least one of the plurality of program loops.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a top view of one embodiment of a NAND string according to aspects of the disclosure;

FIG. 1B is an equivalent circuit diagram of the NAND string according to aspects of the disclosure;

FIG. 2 illustrates a non-volatile storage device that may include one or more memory die or chips according to aspects of the disclosure;

FIG. 3 is a block diagram depicting one embodiment of a sense block according to aspects of the disclosure;

FIG. 4 depicts blocks of NAND flash memory cells in the memory array of FIG. 2 according to aspects of the disclosure;

FIG. 5 depicts an example set of threshold voltage distributions for an eight-state memory device in which each storage element stores three bits of data according to aspects of the disclosure;

FIG. 6 illustrates that Vt distributions can partially overlap according to aspects of the disclosure;

FIG. 7 is a flowchart describing one embodiment of a programming process, which includes one or more verification steps according to aspects of the disclosure;

FIG. 8 illustrates a program verify operation according to aspects of the disclosure;

FIG. 9A illustrates a program verify operation that does not detect a bitcount above a threshold according to aspects of the disclosure;

FIG. 9B illustrates a program verify operation that detect a bitcount above a threshold according to aspects of the disclosure;

FIG. 10A illustrates a voltage levels in program verify iterations according to aspects of the disclosure;

FIG. 10B illustrates a voltage levels in program verify iterations according to aspects of the disclosure;

FIG. 10C illustrates a voltage levels in program verify iterations according to aspects of the disclosure;

FIG. 11 is a flowchart of one embodiment of a process of operating data latches while programming and verifying non-volatile storage according to aspects of the disclosure;

FIG. 12 is a flowchart of one embodiment of a process of operating data latches while programming and verifying non-volatile storage according to aspects of the disclosure;

FIG. 13A, FIG. 13B, FIG. 13C, and FIG. 13D are tables that show status of data latches throughout various stages of the process of FIG. 12 according to aspects of the disclosure;

FIG. 14 shows latch usage during various stages of one embodiment of programming according to aspects of the disclosure;

FIG. 15 is a table showing the number of program loops and verify iterations for each data state in a program operation for triple level cells along with time periods included in each of the program loops according to aspects of the disclosure;

FIG. 16 is a plot of threshold voltage distributions when the program-verify of the highest data state is skipped completely according to aspects of the disclosure;

FIG. 17A is a table illustrating information stored in the first data latch, the second data latch, the third data latch, and the fourth data latch for each data state for triple-level memory cells according to aspects of the disclosure;

FIG. 17B is a table illustrating unused ones of the bit combinations of bits in the first data latch, the second data latch, the third data latch, and the fourth data latch according to aspects of the disclosure;

FIG. 18 is a diagram illustrating example tracking of the memory cells targeted for the highest data state through subsequent ones of the plurality of program loops using the two unused bit combinations for option one according to aspects of the disclosure;

FIG. 19 is another table illustrating information stored in the first data latch, the second data latch, the third data latch, and the fourth data latch for each data state for option one according to aspects of the disclosure;

FIG. 20 is a table illustrating an impact to the cache releases according to aspects of the disclosure;

FIG. 21 summarizes variations of parameters affecting operation of the memory apparatus using option one according to aspects of the disclosure;

FIG. 22 illustrates an example sequence of program loops for option two according to aspects of the disclosure;

FIG. 23 is a plot of threshold voltage distributions when program-verify of the highest data state is skipped after the next highest data state complete and using a counter to track program loops for slow cells targeted for the highest data state according to aspects of the disclosure;

FIG. 24 is a diagram illustrating example tracking of the memory cells along with a corresponding plot of threshold voltage distributions for option three according to aspects of the disclosure;

FIG. 25 shows simulation results for options one, two and three compared to no skipping of the program verify for the highest data state according to aspects of the disclosure;

FIG. 26 is a comparison of no skipping of the program verify for the highest data state, option one, option two, and option three according to aspects of the disclosure;

FIG. 27A is a table illustrating information stored in the first data latch, the second data latch, the third data latch, and a different fourth data latch and a fifth data latch for each data state for four-level memory cells according to aspects of the disclosure;

FIG. 27B is a table illustrating unused ones of the bit combinations of bits in the first data latch, the second data latch, the third data latch, and the different fourth data latch and fifth data latch according to aspects of the disclosure; and

FIG. 28 illustrates steps of a method of operating a memory apparatus according to aspects of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to non-volatile memory apparatuses of the type well-suited for use in many applications. The non-volatile memory apparatus and associated methods of operation of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

In some memory devices or apparatuses, memory cells are joined to one another such as in NAND strings in a block or sub-block. Each NAND string comprises a number of memory cells connected in series between one or more drain-side select gate SG transistors (SGD transistors), on a drain-side of the NAND string which is connected to a bit line, and one or more source-side select gate SG transistors (SGS transistors), on a source-side of the NAND string which is connected to a source line. Further, the memory cells can be arranged with a common control gate line (e.g., word line) which acts a control gate. A set of word lines extends from the source side of a block to the drain side of a block. Memory cells can be connected in other types of strings and in other ways as well.

In a 3D memory structure, the memory cells may be arranged in vertical strings in a stack, where the stack comprises alternating conductive and dielectric layers. The conductive layers act as word lines which are connected to the memory cells. The memory cells can include data memory cells, which are eligible to store user data, and dummy or non-data memory cells which are ineligible to store user data.

Before programming certain non-volatile memory devices, the memory cells are typically erased. For some devices, the erase operation removes electrons from the floating gate of the memory cell being erased. Alternatively, the erase operation removes electrons from the charge-trapping layer.

A programming operation for a set of memory cells typically involves applying a series of program voltages to the memory cells after the memory cells are provided in an erased state. Each program voltage is provided in a program loop, also referred to as a program-verify iteration. For example, the program voltage may be applied to a word line which is connected to control gates of the memory cells. In one approach, incremental step pulse programming is performed, where the program voltage is increased by a step size in each program loop. Verify operations may be performed after each program voltage to determine whether the memory cells have completed programming. When programming is completed for a memory cell, it can be locked out from further programming while programming continues for other memory cells in subsequent program loops.

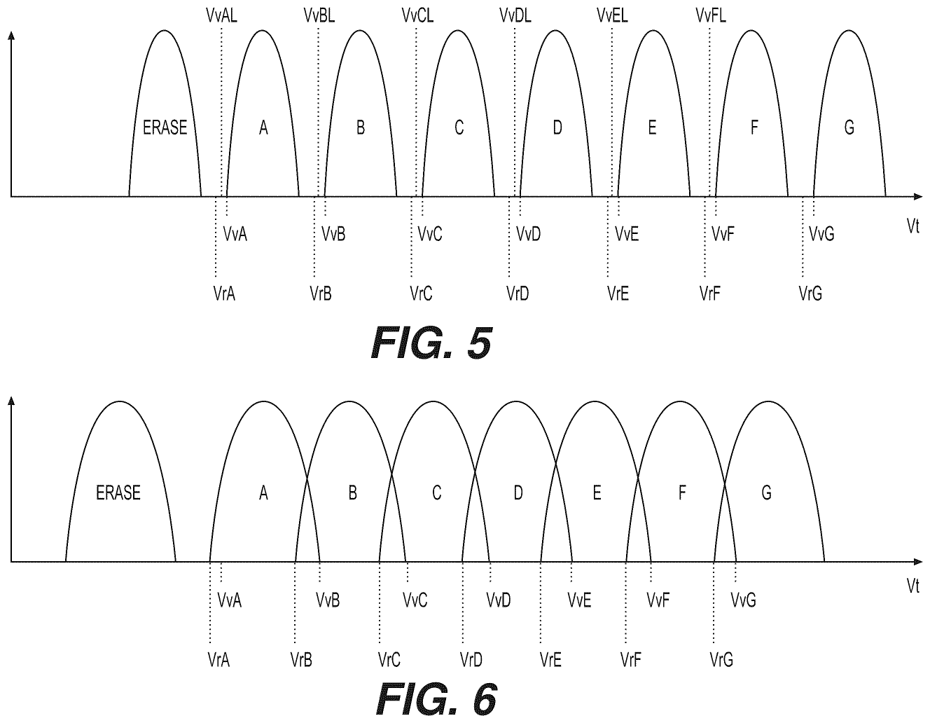

Each memory cell may be associated with a data state according to write data in a program command. Based on its data state, a memory cell will either remain in the erased state or be programmed to a data state (a programmed data state) different from the erased state. For example, in a two-bit per cell memory device, there are four data states including the erased state and three higher data states referred to as the A, B and C data states. In a three-bit per cell memory device, there are eight data states including the erased state and seven higher data states referred to as the A, B, C, D, E, F and G data states (see FIGS. 5 and 6). In a four-bit per cell memory device, there are sixteen data states including the erased state and fifteen higher data states referred to as the Er or S0, S1, S2, S3, S4, S5, S6, S7, S8, S9, S10, S11, S12, S13, S14 and S15 data states.

When a program command is issued, the write data is stored in latches associated with the memory cells. During programming, the latches of a memory cell can be read to determine the data state to which the cell is to be programmed. Each programmed data state is associated with a verify voltage such that a memory cell with a given data state is considered to have completed programming when a sensing operation determines its threshold voltage (Vth) is above the associated verify voltage. A sensing operation can determine whether a memory cell has a Vth above the associated verify voltage by applying the associated verify voltage to the control gate and sensing a current through the memory cell. If the current is relatively high, this indicates the memory cell is in a conductive state, such that the Vth is less than the control gate voltage. If the current is relatively low, this indicates the memory cell is in a non-conductive state, such that the Vth is above the control gate voltage.

The verify voltage which is used to determine that a memory cell has completed programming may be referred to as a final or lockout verify voltage. In some cases, an additional verify voltage may be used to determine that a memory cell is close to completion of the programming. For example, in FIGS. 5 and 6, a memory cell which is to be programmed to the A data state can be subject to verify tests at VvA, a verify voltage of the A data state. In order to improve programming time, some later data states may not be verified until certain earlier data states finish programming. Nevertheless, because every data state is verified, significant programming time is consumed.

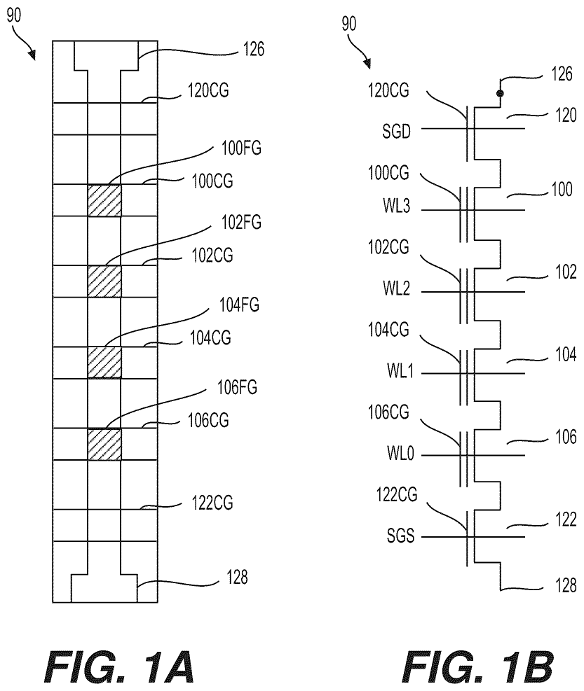

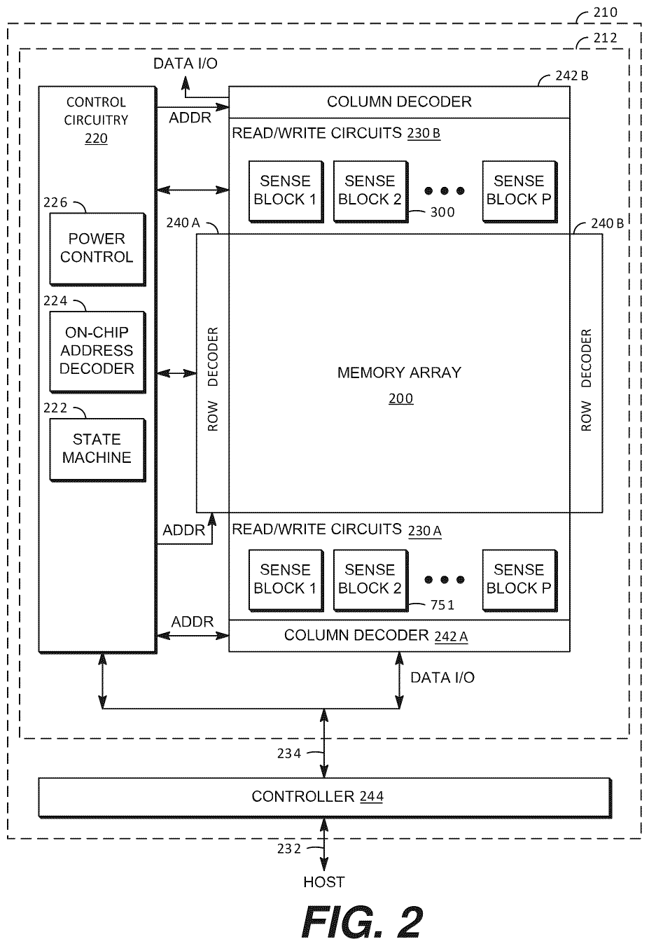

FIG. 1A is a top view showing one NAND string 90. FIG. 1B is an equivalent circuit thereof. The NAND string depicted includes four transistors, 100, 102, 104 and 106, in series and sandwiched between a first select gate 120 and a second select gate 122. Select gate 120 connects the NAND string to bit line 126. Select gate 122 connects the NAND string to source line 128. Select gates 120 and 122 are controlled by applying the appropriate voltages to control gates 120CG and 122CG, respectively. Each of the transistors 100, 102, 104 and 106 has a control gate and a floating gate. Transistor 100 has control gate 100CG and floating gate 100FG. Transistor 102 includes control gate 102CG and floating gate 102FG. Transistor 104 includes control gate 104CG and floating gate 104FG. Transistor 106 includes a control gate 106CG and floating gate 106FG. Control gates 100CG, 102CG, 104CG and 106CG are connected to word lines WL3, WL2, WL1 and WL0, respectively. In one embodiment, transistors 100, 102, 104 and 106 are each memory cells. In other embodiments, the memory cells may include multiple transistors or may be different than that depicted. Select gates 120 and 122 are connected to drain-side select line SGD and source-side select line SGS, respectively. Other types of non-volatile memory in addition to NAND flash memory can also be used.

FIG. 2 illustrates a non-volatile storage device 210 that may include one or more memory die or chips 212. Memory die 212 includes an array (two-dimensional or three dimensional) of memory cells 200, control circuitry 220, and read/write circuits 230A and 230B. In one embodiment, access to the memory array 200 by the various peripheral circuits is implemented in a symmetric fashion, on opposite sides of the array, so that the densities of access lines and circuitry on each side are reduced by half The read/write circuits 230A and 230B include multiple sense blocks 300 which allow a page of memory cells to be read or programmed in parallel. The memory array 200 is addressable by word lines via row decoders 240A and 240B and by bit lines via column decoders 242A and 242B. In a typical embodiment, a controller 244 is included in the same memory device 210 (e.g., a removable storage card or package) as the one or more memory die 212. Commands and data are transferred between the host and controller 244 via lines 232 and between the controller and the one or more memory die 212 via lines 234. One implementation can include multiple chips 212.

Control circuitry 220 cooperates with the read/write circuits 230A and 230B to perform memory operations on the memory array 200. The control circuitry 220 includes a state machine 222, an on-chip address decoder 224 and a power control module 226. The state machine 222 provides chip-level control of memory operations. The on-chip address decoder 224 provides an address interface to convert between the address that is used by the host or a memory controller to the hardware address used by the decoders 240A, 240B, 242A, and 242B. The power control module 226 controls the power and voltages supplied to the word lines and bit lines during memory operations. In one embodiment, power control module 226 includes one or more charge pumps that can create voltages larger than the supply voltage.

In one embodiment, one or any combination of control circuitry 220, power control circuit 226, decoder circuit 224, state machine circuit 222, decoder circuit 242A, decoder circuit 242B, decoder circuit 240A, decoder circuit 240B, read/write circuits 230A, read/write circuits 230B, and/or controller 244 can be referred to as one or more managing circuits.

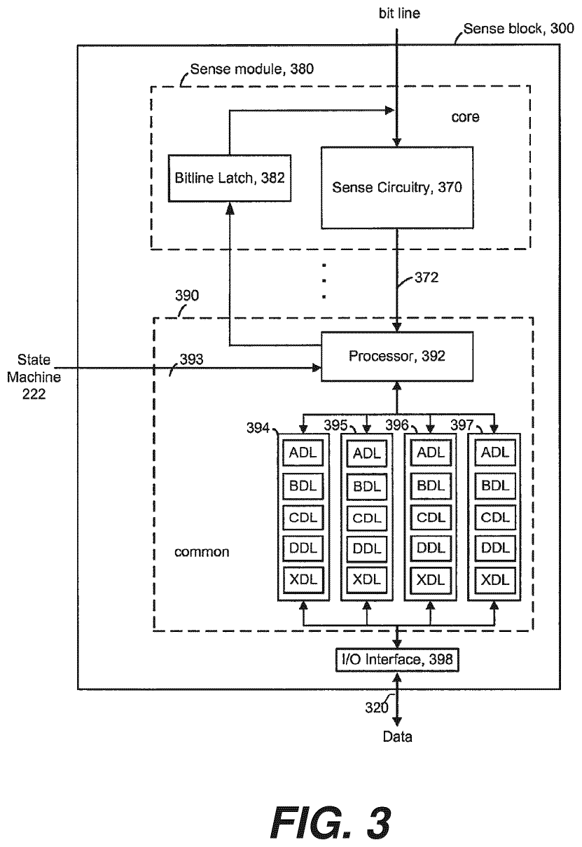

FIG. 3 is a block diagram depicting one embodiment of a sense block 300. An individual sense block 300 is partitioned into a core portion, referred to as a sense module 380, and a common portion 390. In one embodiment, there is a separate sense module 380 for each bit line and one common portion 390 for a set of multiple sense modules 380. In one example, a sense block 300 will include one common portion 390 and eight sense modules 380. Each of the sense modules in a group will communicate with the associated common portion via a data bus 372.

Sense module 380 comprises sense circuitry 370 that determines whether a conduction current in a connected bit line is above or below a predetermined threshold level. Sense module 380 also includes a bit line latch 382 that is used to set a voltage condition on the connected bit line. For example, a predetermined state latched in bit line latch 382 will result in the connected bit line being pulled to a state designating program inhibit (e.g., 1.5-3 V). As an example, a flag=0 can inhibit programming, while flag=1 does not inhibit programming.

Common portion 390 comprises a processor 392, five example sets of data latches 394 and an I/O Interface 398 coupled between the sets of data latches 394 and data bus 320. One set of data latches can be provide for each sense module, and five data latches identified by ADL, BDL, CDL, DDL, XDL may be provided for each set. The use of the data latches is further discussed below.

Processor 392 performs computations. For example, one of its functions is to determine the data stored in the sensed storage element and store the determined data in the set of data latches. At least some of the data latches in a set of data latches (e.g., 394) are used to store data bits determined by processor 392 during a read operation. At least some of the data latches in a set of data latches are also used to store data bits imported from the data bus 320 during a program operation. The imported data bits represent write data meant to be programmed into the memory. I/O interface 398 provides an interface between data latches 394-397 and the data bus 320.

In one embodiment, a user is able to stream data to be programmed into a storage element into the XDL latch. This program data may be transferred to the ADL, BDL, and CDL latches at the beginning of the program operation. Note this describes programming three bits per memory cell. In one embodiment, during a read operation, the ADL, BDL and CDL latch are used to store the three bits that are read from the memory cell. The user is able to toggle the read data out through the XDL latch in one embodiment.

In one embodiment, the user has access to the XDL latch, but not to the ADL, BDL, or CDL latches. For example, the user may be able to access the XDL latch to perform background caching during a program operation. Background caching is discussed in more detail below. In one embodiment, the user has limited access to the XDL during a program operation. For example, the user may be able to stream program data into the XDL latch prior to the programming operation. However, the user may not have access to the XDL latch during one embodiment of programming. In one embodiment, the XDL latch is used to store “lockout data” for the memory cell during a program operation. Briefly, the lockout data may indicate that a storage element is locked out from further programming. Further details are discussed below.

During reading or other sensing, the state machine 222 controls the supply of different control gate voltages to the addressed storage element. As it steps through the various control gate voltages corresponding to the various memory states supported by the memory, the sense module 380 may trip at one of these voltages and an output will be provided from sense module 380 to processor 392 via bus 372. At that point, processor 392 determines the resultant memory state by consideration of the tripping event(s) of the sense module and the information about the applied control gate voltage from the state machine via input lines 393. It then computes a binary encoding for the memory state and stores the resultant data bits into data latches (e.g., 394). In another embodiment of the core portion, bit line latch 382 serves both as a latch for latching the output of the sense module 380 and as a bit line latch as described above.

Some implementations can include multiple processors 392. In one embodiment, each processor 392 will include an output line (not depicted) such that each of the output lines is wired-OR'd together. In some embodiments, the output lines are inverted prior to being connected to the wired-OR line. This configuration enables a quick determination during the program verification process of when the programming process has completed because the state machine receiving the wired-OR can determine when all bits being programmed have reached the desired level. For example, when each bit has reached its desired level, a logic zero for that bit will be sent to the wired-OR line (or a data one is inverted). When all bits output a data 0 (or a data one inverted), then the state machine knows to terminate the programming process. Because each processor communicates with eight sense modules, the state machine needs to read the wired-OR line eight times, or logic is added to processor 192 to accumulate the results of the associated bit lines such that the state machine need only read the wired-OR line one time. Similarly, by choosing the logic levels correctly, the global state machine can detect when the first bit changes its state and change the algorithms accordingly.

During program or verify, the data to be programmed is stored in the set of data latches 394-397 from the data bus 320. The program operation, under the control of the state machine, comprises a series of programming voltage pulses applied to the control gates of the addressed storage elements. Each program pulse is followed by a read back (verify) to determine if the storage element has been programmed to the desired memory state. Processor 392 monitors the read back memory state relative to the desired memory state. When the two are in agreement, the processor 392 sets the bit line latch 382 so as to cause the bit line to be pulled to a state designating program inhibit. This inhibits the storage element coupled to the bit line from further programming even if program pulses appear on its control gate. In other embodiments, the processor initially loads the bit line latch 382 and the sense circuitry sets it to an inhibit value during the verify process.

Each set of data latch stacks 394-397 contains a stack of data latches corresponding to the sense module 380, in one embodiment. In one embodiment, there are five data latches per sense module 380. The ADL, BDL, and CDL data latches can be implemented as a shift register so that the parallel data stored therein is converted to serial data in the XDL latch for transfer across data bus 320, and vice-versa. All the ADL, BDL, and CDL data latches corresponding to the read/write block of m storage elements can be linked together to form a block shift register so that a block of data can be input or output by serial transfer. In particular, the bank of read/write modules may be adapted so that each of its set of ADL, BDL, and CDL data latches will shift data in to or out of the XDL latch in sequence as if they are part of a shift register for the entire read/write block.

In one embodiment, one purpose of the ADL, BDL, and CDL latches is to store data that is to be programmed into a storage element. For example, the storage elements may store three bits per storage element. In one embodiment, the storage elements store four bits per storage element. In this case, there may be an additional data latch (not depicted in FIG. 3) for storing the fourth bit of data that is to be programmed into a storage element. In one embodiment, the storage elements store only two bits per storage element, in which case one of the ADL, BDL, and CDL latches is not needed. The storage elements could store more than four bits per storage element, in which case there may be one data latch for each bit.

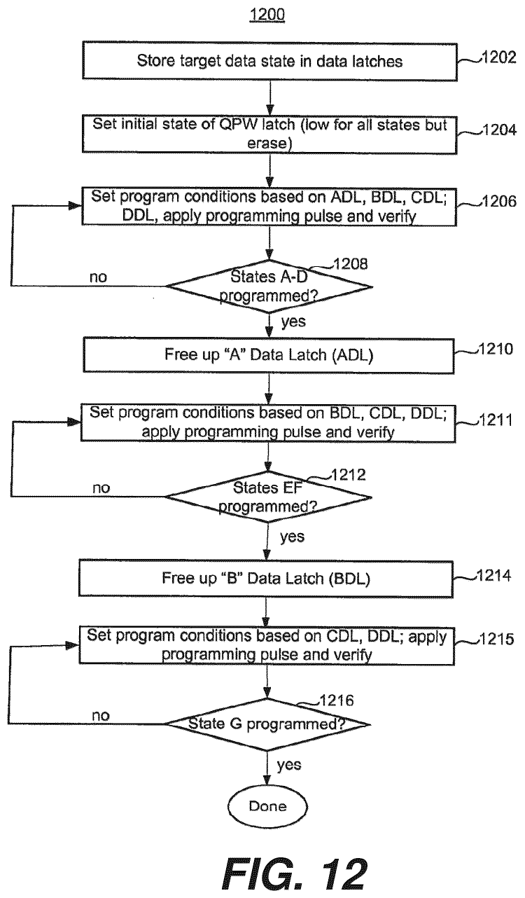

In one embodiment, the ADL, BDL, and CDL latches may also be used to store status information during programming. For example, after the storage element has reached its target threshold voltage, each latch (ADL, BDL, CDL) could be set to “1” to indicate that programming is complete for this storage element. In one embodiment, the latches are used differently as programming proceeds to different stages. In one embodiment, the ADL latch is freed up during programming. In one embodiment, the BDL latch is also freed up during programming. Further details are discussed in connection with FIGS. 12, 13A-13D, and 14, and elsewhere.

In one embodiment, the DDL latch is used to store status information during programming. In one embodiment, programming is slowed as the storage element nears the target threshold level. For example, the DDL latch may identify that a storage element's Vth is above a lower verify level (e.g., VvaL or VvbL in FIG. 5). If that storage element is not yet locked out, then it may receive slower programming. If the DDL latch indicates the storage element's Vth is below the lower verify level, then it may be in a fast programming mode. Further details are discussed below.

In one embodiment, the XDL latch is used to store status information during programming. After the data from the XDL latch has been shifted in to the ADL, BDL, and CDL data latches, the XDL latch may be set to an initial state (e.g., “0”). After a memory cell has reached its target threshold voltage, the XDL latch may be set to another state (e.g., “1”). Thus, the XDL latch may store “lockout status.” Therefore, the program data in the ADL, BDL, and CDL latches may be preserved both during and after the program operation. Further details are discussed below.

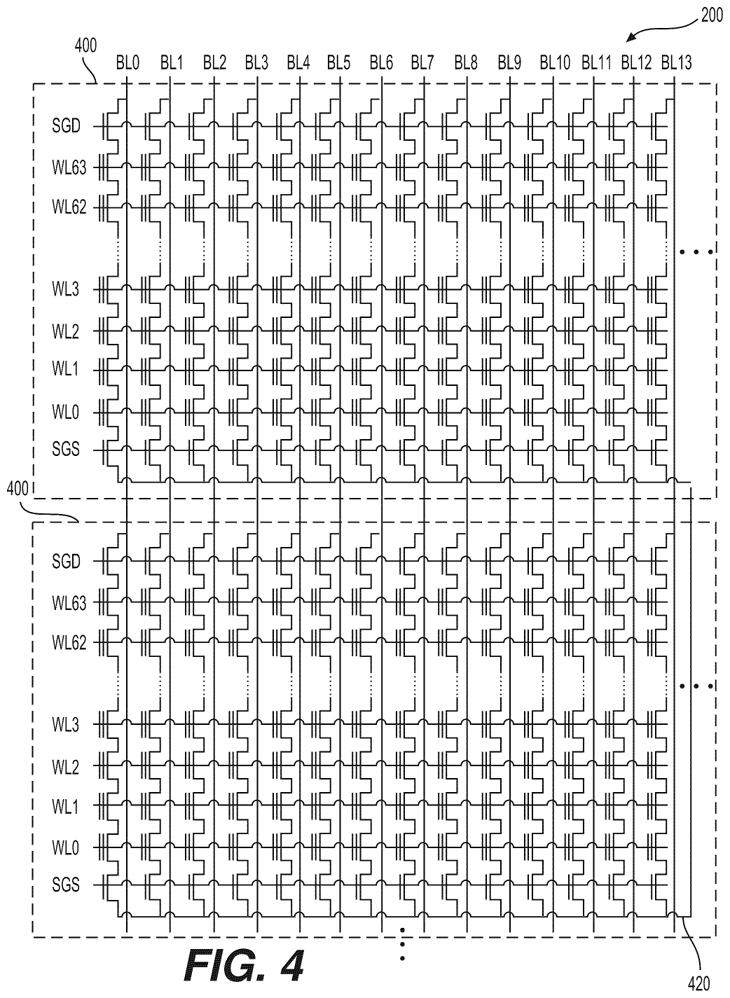

FIG. 4 depicts blocks of NAND flash memory cells in the memory array 200 of FIG. 2. The memory array can include many blocks 400. Two example blocks 400 are depicted in FIG. 4. Each block 400 includes a number of NAND strings. A set of bit lines, e.g., BL0, BL1, . . . may be shared among the blocks. Thus, each NAND string is associated with one bit line. Each NAND string is connected at one end to a drain select gate (SGD), and the control gates of the drain select gates are connected via a common SGD line. The NAND strings are connected at their other end to a source select gate which, in turn, is connected to a common source line 420. Sixty-four word lines, for example, WL0-WL63, extend between the source select gates and the drain select gates.

Other types of non-volatile memory in addition to NAND flash memory can also be used. For example, another type of memory cell useful in flash EEPROM systems utilizes a non-conductive dielectric material in place of a conductive floating gate to store charge in a non-volatile manner. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. Other types of non-volatile memory are also known.

Note that there may be thousands, or tens of thousands of bit lines. Therefore, a single word line may be used by tens of thousands of storage elements. Typically, there is a driver at one and of the word line that provides the read reference voltages or the programming voltages.

FIG. 5 depicts an example set of threshold voltage distributions for an eight-state memory device in which each storage element stores three bits of data. A first threshold voltage (Vth) distribution is provided for erased (Er-state) storage elements. Seven Vth distributions represent programmed states A through G. In one embodiment, the threshold voltages in the Er-state are negative and the threshold voltages in the A-G distributions are positive. However, all or a part of the threshold distribution in the Er-state may be positive. Also, all or a part of the threshold distribution of the A-state may be negative (likewise for other data states).

Read reference voltages, Vra, Vrb, Vrc, etc. are also provided for reading data from storage elements. By testing whether the threshold voltage of a given storage element is above or below Vra, Vrb Vrc, etc. the system can determine the state, e.g., programming condition, the storage element is in.

Further, verify reference voltages, Vva, Vvb Vvc, etc. are provided. When programming storage elements to the A-state, B-state, C-state, etc. the system will test whether those storage elements have a threshold voltage greater than or equal to Vva, Vvb Vvc, etc.

In one embodiment, known as full sequence programming, storage elements can be programmed from the Er-state directly to any of the programmed states A-G. For example, a population of storage elements to be programmed may first be erased so that all storage elements in the population are in the Er-state. A series of program pulses will then be used to program storage elements into their respective target states A-G. While some storage elements are being programmed from the Er-state to the A-state, other storage elements are being programmed from the Er-state to the B-state, etc.

FIG. 5 also shows verify low reference voltages VvAL, VvBL, VvCL, etc. These reference voltages may be used during a program verify operation to determine whether a storage element is near its intended target threshold. If so, then programming speed may be slowed down. In one embodiment, Vdd is applied to bit lines that have reached their target state and are inhibited from further programming. Bit lines of storage elements that are still below the verify low level may be grounded to allow for fast programming. However, when between the verify low level and the normal verify level, the bit line may receive an intermediate voltage (e.g., between ground and Vdd) to cause slow or moderate speed programming. As one example, the intermediate voltage could be about 0.6V to 0.8V. However, the intermediate voltage could be either below or above this range. In one embodiment, the DDL latch indicates where the storage element is in this programming sequence. Further details are discussed below. In one embodiment, storage elements being programmed to the G-state do not receive the slow (or moderate) speed programming. Hence, no verify low reference voltage is depicted in FIG. 5 for the G-state. However, there may be a VvGL for the G-state, if desired.

In one embodiment, multiple passes may be used to program the storage elements. For example, one pass may be used to program each bit. Thus, in the case of storing three bits per memory cell, there may be three passes. In the case of storing two bits per memory cell, there may be two passes. In one embodiment, a multi-state storage element stores data for three different pages: a lower page, a middle page, and an upper page. The eight states, and the bits they represent, may be: Er-state (111), A-state (011), B-state (101), C-state (001), D-state (110), E-state (010), F-state (100), and G-state (000). For Er-state, all pages store a “1.” For A-state, the lower page stores a “0”, the middle page stores a “1” the upper page stores a “1.” Other states can be deduced in a similar manner. Note that although specific bit patterns have been assigned to each of the states, different bit patterns may also be assigned. Also note that this bit and page assignment may be used for other programming sequences, such as the fast/slow programming described above.

In the first programming pass of one embodiment, the lower page is programmed for a selected word line WLn. If the lower page is to remain data 1, then the storage element state remains at the Erased state. If the data is to be programmed to 0, then the threshold voltage of the storage elements on WLn are raised such that the storage element is programmed to an intermediate state. This intermediate state could have a lower tail just below VvD. In the second programming pass of one embodiment, the middle page is programmed for a selected word line WLn. This results in the creation of two more threshold voltage distributions (one additional from each of the former distributions). In the third programming pass of one embodiment, the upper page is programmed for a selected word line WLn. This results in the creation of four more threshold voltage distributions (one additional from each of the former four distributions).

Although the programming examples depict eight data states and three pages of data, the concepts taught can be applied to other implementations with more or fewer than eight states and more or fewer than three pages. Moreover, in the example programming techniques discussed, the Vth of a storage element is raised gradually as it is programmed to a target data state. However, programming techniques can be used in which the Vth of a storage element is lowered gradually as it is programmed to a target data state. Programming techniques which measure storage element current can be used as well. The concepts herein can be adapted to the different programming techniques.

FIG. 6 illustrates that Vt distributions can partially overlap since the error correction algorithm can handle a certain percentage of cells that are in error. Note that in some embodiments, at one point in time the threshold voltage distribution may resemble FIG. 5 and at another time the threshold voltage distributions may overlap, as in FIG. 6. For example, just after programming, the threshold voltage distribution may resemble FIG. 5. However, over time, the threshold voltages of memory cells may shift, such that there may be overlap.

However, there may be overlap between at least some neighboring threshold distributions immediately after programming. Note that it can be very difficult to detect word line defects when there is overlap between neighboring Vt thresholds.

Also note that contrary to the equal spacing/width of the depicted threshold voltage distributions, various distributions may have different widths/spacings in order to accommodate varying amounts of susceptibility to data retention loss.

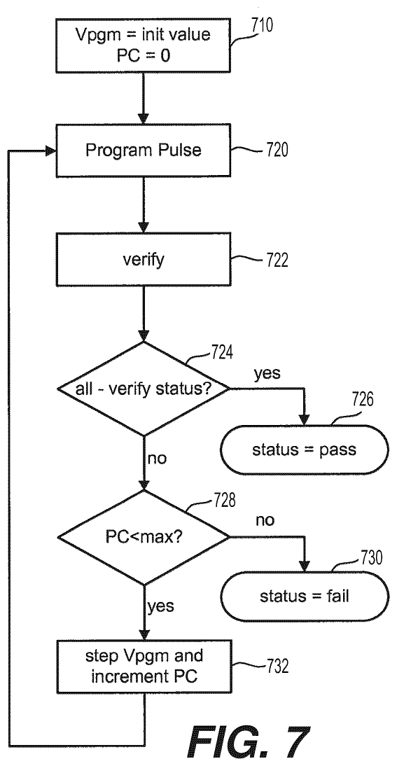

FIG. 7 is a flowchart describing one embodiment of a programming process, which includes one or more verification steps. In step 810, the program voltage (Vpgm) is set to an initial value. Also, in step 710, a program counter (PC) is initialized to zero. In step 720, a program pulse is applied.

In step 722, a verification process is performed. In one embodiment, the verification is a concurrent coarse/fine verify. Referring to FIG. 5, some memory cells that are being programmed to the A-state are verified for the VvaL level, while others that are being programmed to the A-state are verified for the Vva level. During the initial programming steps in which the memory cell's threshold is well below the final level (Vva), course programming is applied. However, after the memory cell's threshold voltage reaches VvaL, fine programming is used. Thus, while some memory cells are being verified for coarse programming, other memory cells are being verified for fine programming. Note that with course/fine programming, some memory cells are being verified for one state (e.g., A-state), while others are being verified for another state (e.g., B-state). Note that when a particular memory cell has been verified as being programmed to its intended state, it may be locked out from further programming.

However, note that if there is a break on the selected word line being programmed, then the verification may produce an erroneous result. As noted above, a break in the word line could result in storage elements on the far side of the break receiving a reference voltage that is smaller than intended. For example, storage elements that are intended to be programmed to the G-state should receive the reference voltage VvG (see FIG. 5) at their control gate. However, they may in fact receive a lower voltage due to the break. Under normal circumstances, if a storage element has not yet reached its target state (e.g., its actual Vt is below the reference voltage), the storage element will turn on in response to the verify voltage. On the other hand, if a storage element has reached its target state (e.g., its actual Vt is at or above the reference voltage) it should not turn on. For example, consider the case of a storage element being targeted for the G-state. This storage element will be verified by applying VvG to the selected word line. If its actual Vt is below VvG it will conduct a current. After its actual Vt is above VvG it will no longer turn on, indicating it has reached its target state.

However, since storage elements beyond the break receive too low of a verify voltage, they may fail to turn on when their actual Vt is below the target Vt. A storage element past the break might see a lower verify voltage than intended. For example, a storage element that is targeted for the G-state might should see a verify voltage of VvG, but might experience a lower voltage at its control gate. As one particular example, the storage example might only see a verify voltage of VvF, if it is past the break. Therefore, in this particular example, when its actual Vt is greater than VvF it will pass the verify test. In general, the storage element past the break could pass the verify test if its actual threshold voltage is below VvG. Therefore, programming will stop for that storage element. However, it may in fact be under-programmed.

In step 724, it is determined whether all of the memory cells have verified that their threshold voltages are at the final target voltage for that memory cell. If so, the programming process is completed successfully (status=pass) in step 726. If all of the memory cells are not all verified, then it is determined whether the program counter (PC) is less than a maximum value such as 20. If the program counter (PC) is not less than max (step 728), then the program process has failed (step 730). If the program counter (PC) is less than a maximum value (e.g., 20), then the program counter (PC) is incremented by 1 and the program voltage is stepped up to the next pulse in step 832. Subsequent to step 732, the process loops back to step 720 and the next program pulse is applied to the memory cells.

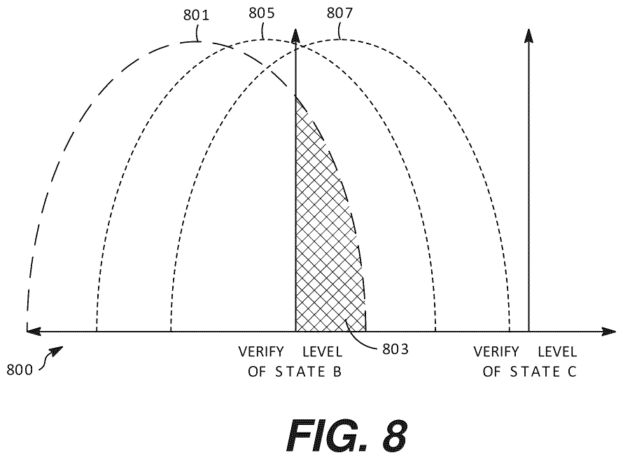

FIG. 8 shows a diagram 800 with a threshold voltage (Vt) distribution during the middle of program operation and verifying a first memory state, here shown as the State B, and a second memory state, here state C. While the states B and C are used to illustrate the present concept, it will be recognized that the other consecutive states can also use similar principals. Voltage is represented on the abscissa.

In NAND memory, the logical value stored in a memory cell is determined by the voltage window in which the cell's Vt lies. The Vt is the voltage stored in a cell after the program pulse. As cell size is scaled down and more bits per cell are stored, the threshold voltage window used to represent each value becomes smaller, leading to increased error rates in determining a cell's value. This is because process variations become more prevalent when the amount of charge stored in a flash cell reduces with feature size, leading to the Vt of different cells storing the same value becoming significantly different. Hence, deciding what logical value to which a cell's threshold voltage corresponds is becoming increasingly difficult while it is necessary for reliability.

After respective program pulses are applied to the memory cells, the operation of the memory performs a verification step which can detect the distribution of the voltages stored in the memory cells. Each memory state (e.g., A-G states) has its own Vt, which increases with each successive state. The Vt distribution 801 results from a first program pulse being applied to the memory cells and shows the bitscan count of the number of memory cells as function of voltage. An upper tail of the distribution 801 includes some scanned bits (memory cells) that exceed the voltage verify level of State B. This is represented in area 803 to the right of the voltage verify level of State B. If the bitscan count in area 803 does not exceed a threshold value, then the memory system will apply the next program pulse, which will result in the distribution 805. If the bitscan count in area 803 meets or exceeds a threshold value, then the memory system will trigger the program verify pulse for C state, which results in bit scan distribution 805. No prior program verify have been applied for C state before triggering, which saves several program verify count and be known as smart skip program verify. This subsequent program pulse and verify will result in the distribution 807 beyond distribution 805 (at a higher voltage). In an example embodiment, when a Vt distribution at certain memory cell state, e.g., any of A through F states, then the verify process can trigger the verify for next voltage level in the same verify process without triggering the next program pulse. In an example embodiment, the verify process counts bits to the right of the Vt of state B and triggers the verify for C state occurs in the same verify loop as the sensing of the bits that exceed the Vt of the B state.

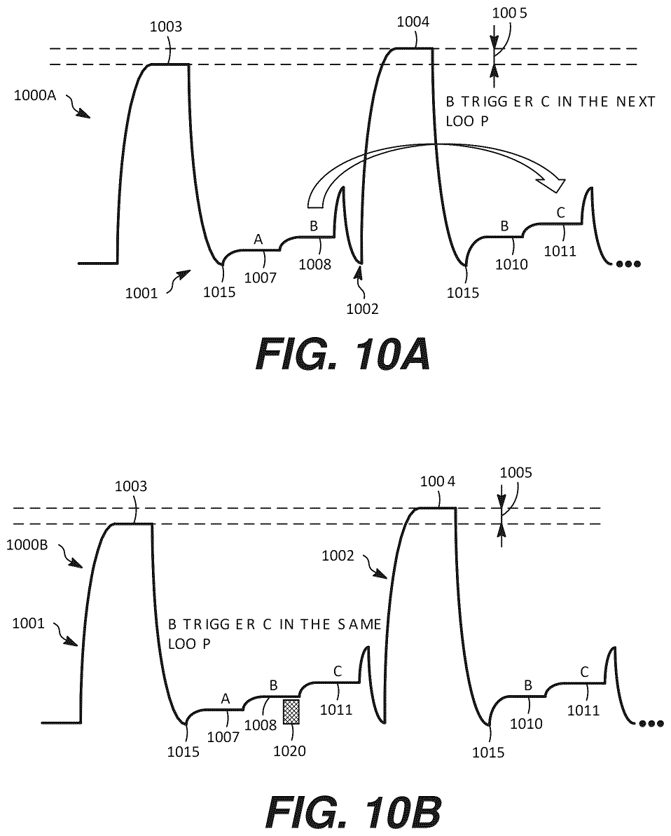

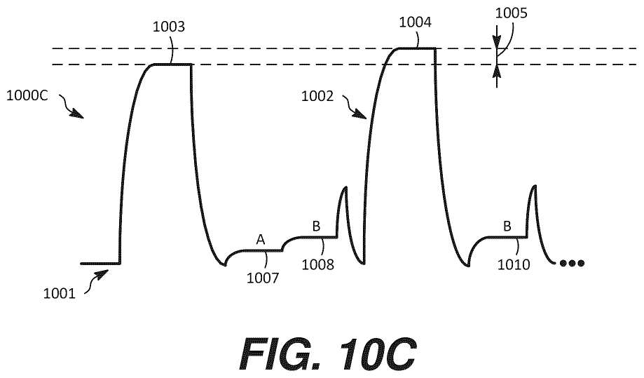

During a program verify operation in the memory, an example embodiment typically performs a program verify of all states, e.g., A-G states, along a set scheme. See, e.g., FIG. 10A of U.S. Pat. No. 10,014,063, which is hereby incorporated by reference in its entirety. In some practical applications, performing verify of the C to G states after a first program pulse can be a waste of time and resources. Therefore, smart skip program verify detects when an upper tail of a lower state (e.g., A or B state) is above some threshold value and triggers the program verify for the next higher state prior to starting a next program/verify loop. This can reduce unnecessary program/verify loop for the higher state at subsequent program loop. In order to trigger the next state verify, there is a pre-defined bit count in the memory circuitry and during the program operation, when the bit scan result shows that upper tail has a higher bit count compared to a stored threshold value (or reaches the threshold value), the methodology triggers the next state verify after next program pulse.

The smart skip program verify operation detects the upper tail of “n” state and determines if triggering n+1 state verify based on the threshold value. The threshold value can be set based on statistical analysis of the memory device. If is desirable to determine when to skip to the next state (n+1) from the current state (n) being verified as even using the minimum voltage increase of the programing voltage, the earliest program verify initiates on the next loop (n+1 loop) instead of the current loop (n) can result in an over programming.

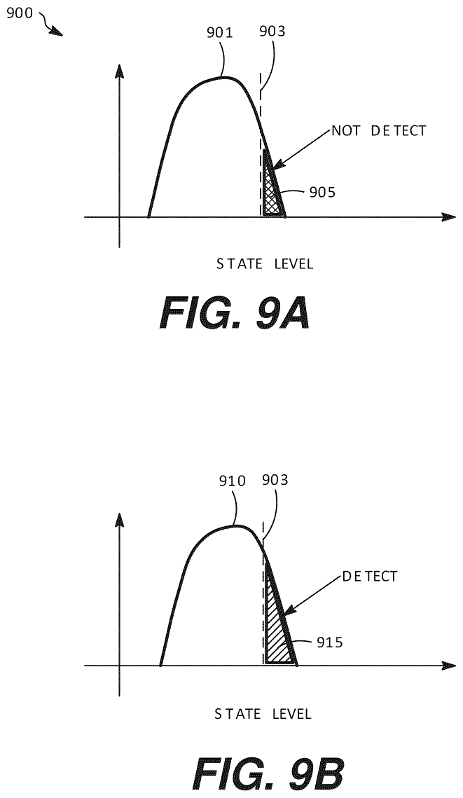

FIG. 9A shows a diagram 900 that includes a threshold voltage distribution 901, i.e., bitscan counts, from a verify operation. This is used to verify the programmed bit values stored in the addressed memory cells at the state verify level 903. The area 905 to the right of the voltage level and under the curve of the verify pulse 901 (its upper tail) is the count of bitscans (i.e., the count of memory cells whose voltage exceeds the state voltage level). The area 905 does not show enough count to exceed the threshold value to trigger a skip to the next state level in the same verify iteration.

FIG. 9B shows a diagram that includes threshold voltage distribution 910, i.e., bitscan counts, from a verify operation. This is used to verify the programmed bit values stored in the addressed memory cells at the state level 903. The area 915 to the right of the voltage level and under the curve of the verify pulse 910 (e.g., the upper tail of distribution 910) is the count of bitscans (i.e., the number of memory cells whose voltage exceeds the state voltage level). The area 905 does show enough count to exceed the threshold value and trigger a program verify to the next state level in the same verify iteration. In an example embodiment, the methodology, will trigger a verify before applying the next program pulse.

FIG. 10A shows a program verify operation 1000A with two program verify iterations. The operation 1000A is a partial example of a memory cell programming operation for a multi-state memory device having an erased state (Er) and three programmed memory states (e.g., A, B, C). The horizontal axis depicts time. The vertical axis depicts control gate or word line voltage. Generally, a programming operation can involve applying a pulse train to a selected word line, where the pulse train includes multiple program loops or program-verify iterations. The program portion of the program-verify iteration includes a Vpgm pulse (voltage pulses 1003 or 1004), and the verify portion of the program-verify iteration includes one or more verify pulses (e.g., voltage pulses 1007, 1008 or voltage pulses 1010, 1011).

For each Vpgm pulse 1003, 1004, a square waveform is depicted for simplicity, although other shapes are possible such as a multilevel shape or a ramped shape. Further, Incremental Step Pulse Programming (ISPP) is used in this example, in which the Vpgm pulse amplitude steps up in each successive program loop shown as the voltage increase 1005. This example uses ISPP in a single programming pass in which the programming is completed. ISPP also can be used in each programming pass of a multi-pass operation.

A pulse train typically includes Vpgm pulses which increase stepwise in amplitude by in each program-verify iteration using a fixed or varying step size, e.g., voltage step 1005. A new pulse train starts at an initial Vpgm pulse level (for e.g., for an A level) and ends at a final Vpgm pulse level (e.g., at a G level for a three bits multi-level memory) which does not exceed a maximum allowed level.

Operation 1000A includes a series of Vpgm pulses 1003, 1004 that are applied to a word line selected for programming, and an associated set of non-volatile memory cells. One, two or three verify voltage pulses are provided after each Vpgm pulse as an example, based on the target memory states which are being verified. A voltage of 0V (here shown at 1015) may be applied to the selected word line between the Vpgm pulses 1003, 1004 and verify voltage pulses 1007, 1008 and 1010, 1011.

In an embodiment, A-state verify voltage VvA (e.g., waveform or signal 1007) may be applied after the first Vpgm pulse 1003. The B-state verify voltage VvB (e.g., waveform or signal 1008) may be applied after the waveform 1007. The bitscan occurs to count the number of memory cells that exceed the B-state level. This is the operation shown and described with reference to FIG. 9B. As the bitscan count exceeds a threshold value, the memory controller triggers the operation 1000A in the next iteration 1002 to trigger the C-state level verify signal 1001.

The next iteration 1002 increases the Vpgm pulse 1004 by voltage 1005 from the first program pulse 1003. The signal level is dropped to about zero volts and then the B-state and C-state program verify pulses 1010, 1011 are applied. B-state verify voltage VvB (e.g., waveform or signal 1010) may be applied after the second Vpgm pulse 1003. The C-state verify voltage VvC (e.g., waveform or signal 1011) may be applied after the waveform 1010. Thus, the bitcount of the B-state triggered the verify of the C-state in a subsequent verify iteration.

FIG. 10B shows a program operation 1000B, which is similar to operation 1000A with same signal, e.g., voltage levels, being designated with the same reference numbers as in FIG. 10A. However, there is a difference. When the bitcount from the bitscan occurring at the B-state, e.g., based on signal 1008, it triggers the operation 1000B to conduct the C-level verify in the same iteration. That is, the C-level verify is performed in the same iteration as the preceding B-state that exceeded the threshold value for the bitscan count. The initial C-level verify occurs before the incremented program signal 1004. This is schematically shown at box 1020 whereat the bitscan count of B-state occurs and the memory controller detects that the count threshold is met or exceeded. The memory controller then applies the next verify state level before proceeding to the iteration 1002.

While the above example uses the A-state, the B-state, and the C-state for illustrative purposes, it is within the scope of additional embodiments to apply the same determination of the bitscan count meeting or exceeding the count threshold to trigger the verification of the next state. For example, the C-state can trigger the D-state verify in the same iteration. The D-state bitscan count determination can trigger the E-state verify in the same iteration. The E-state bitscan count determination can trigger the F-state verify in the same iteration. The F-state bitscan count determination can trigger the G-state verify in the same iteration.

FIG. 10C shows a program and verify operation 1000C that is similar to FIGS. 9A and 9B, and the same elements are designated with the same reference numbers. However, this operation 1000C is when the bitscan count for the B-state does not exceed or meet the threshold value. This is the operation 1000C that results from the embodiment shown in FIG. 9A. The C-state is not triggered early by a count in the first iteration and thus is not in the second iteration 1002 or triggered in the first iteration 1001.

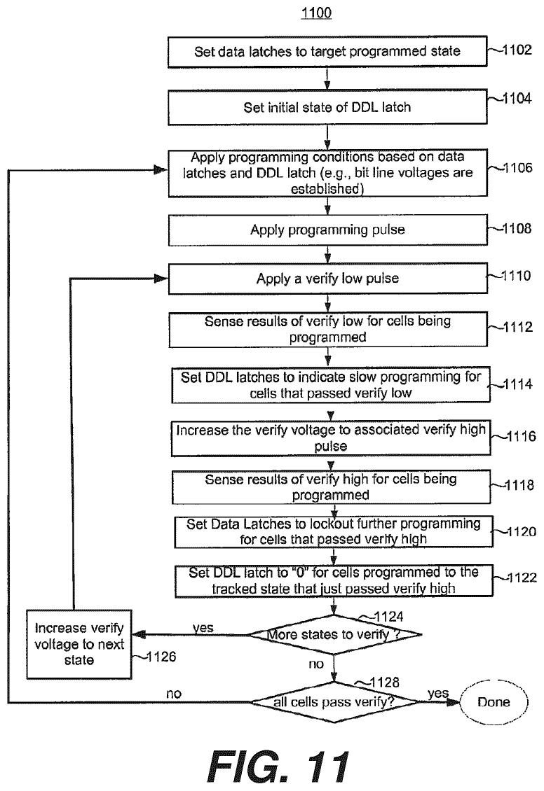

FIG. 11 is a flowchart of one embodiment of a process 1100 of operating data latches while programming and verifying non-volatile storage. Process 1100 provides details of maintaining information that indicates which storage elements were programmed to a particular state. Note that data latches that initially indicate which state that a storage element is to be programmed to may be freed up during programming. Therefore, this information may be lost during the programming process. In one embodiment, the process 1100 “tracks” or maintains information for one state. By tracking a state, it is meant that the process 1100 maintains information after the programming is over as to which storage elements were intended to be programmed to a particular (tracked) state. Note that this may be the erased state, as well as any of the programmed states.

Process 1100 provides further details of one embodiment of steps 1002 and 1004 from FIG. 10. Reference will be made to a set of data latches 394 in FIG. 3. As noted above, three data latches ADL, BDL, and CDL initially store the data to be programmed into the storage element. Thus, the storage element stores three bits, in one embodiment. The fourth data latch, DDL, is used for what is referred to herein as “quick pass write” (QPW) status. Note that there could be more or fewer than four latches.

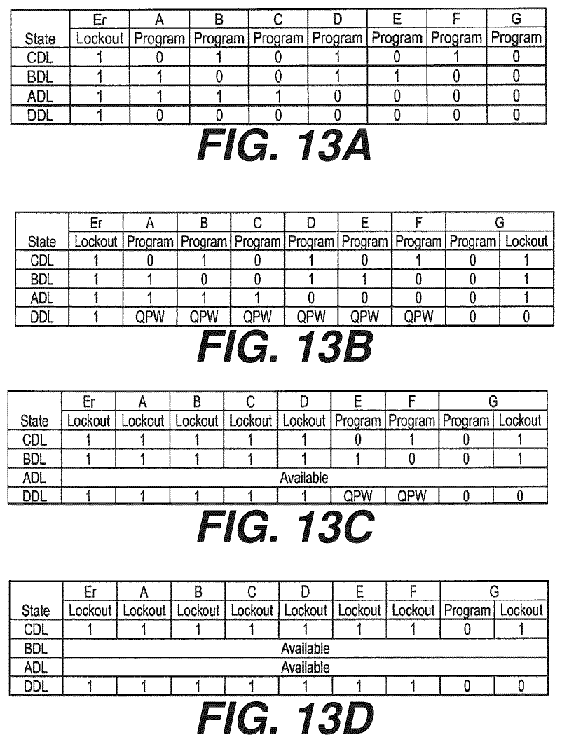

In step 1102, data latches are set to their target program state. In one embodiment, ADL, BDL, and CDL latches are set as indicated in FIG. 13A. Note that a different bit assignment may be used.

In step 1104, the DDL latch is set to an initial state. In one embodiment, the DDL latch is set as indicated in FIG. 13A. In that embodiment, the DDL latch for all storage elements is set to “0” except for those that are to remain in the erase-state. In one embodiment, every DDL latch is set to “0”. In one embodiment, setting the DDL latch for all states to “0” is used when tracking the erased state.

In step 1106, programming conditions are applied based at least in part on the data latches. In one embodiment, bit line voltages are set. In one embodiment, three categories are used. One for storage elements that are locked out (or inhibited) from any further programming, one is for storage elements that are still undergoing fast programming, and one is for storage elements that are to receive slower programming because they are near their target threshold voltages.

In one embodiment, bit lines for storage elements locked out or inhibited storage elements are set to Vdd, bit lines for storage elements undergoing nominal (or fast) programming are set to ground (e.g., Vss), bit lines for the third category are set to an intermediate voltage between ground and Vdd. This intermediate voltage slows down the programming to some extent.

In step 1108, one or more programming pulses are applied to the selected word line. A pass voltage (e.g., Vpass) may be applied to unselected word lines.

In step 1110, a verify low pulse is applied to the selected word line. Referring to FIG. 5, VvAL may be applied. In step 1112, sensing is performed to determine whether storage elements that were intended to be programmed to the state associated with the verify low pulse have reached the verify low point. For example, storage elements intended to be programmed to the A-state (as indicated in ADL, BDL, CDL) are sensed to determine whether their threshold voltage is at or above VvAL. In one embodiment, the current of the bit line is sensed.

In step 1114, the DDL latches are set based on the results of step 1112. Note that the DDL latches in question are those associated with the state that was just verified. In one embodiment, the DDL latch is set to “1” to indicate that slow programming is to be performed. For example, storage elements intended to be programmed to the A-state that have a threshold voltage above VvAL have their DDL latch set to “1”.

In step 1116, the verify reference voltage is increased to the associated verify high reference voltage for the present state being verified. For example, the reference voltage is set to VvA (see, FIG. 5). In one embodiment, step 1116 involves increasing the voltage on the selected word line.

In step 1118, sensing is performed to determine whether storage elements that were intended to be programmed to the state associated with the nominal verify pulse have reached the nominal verify point. For example, storage elements intended to be programmed to the A-state are sensed to determine whether their threshold voltage is at or above VvA. In one embodiment, the current of the bit line is sensed.

In step 1120, the ADL, BDL, and CDL latches are set based on the results of step 1120. Note that the latches in question are those associated with the state that was just verified. In one embodiment, one or more of the ADL, BDL, and CDL latches are set to “1” to indicate that programming is to be inhibited. For example, storage elements intended to be programmed to the A-state that have a threshold voltage above VvA have their ADL, BDL, and CDL latches set to “1”.

Under some conditions only one or two of the data latches may be needed to indicate the lockout conditions. Thus, step 1120 includes setting one or more of latches ADL, BDL, and CDL to “1”, in one embodiment. In one embodiment, the process 1100 keeps track of how far along the programming process is, and uses a different set of latches to indicate lockout depending on which stage programming is in. Further details are discussed below.

In step 1122, the DDL latch of storage elements being tracked may be set to “0”, if they just passed program verify. For example, if the A-state is the being tracked, then the DDL latch of those storage elements that just passed program verify for the A-state have their DDL latch set to “0”. However, if a state other than the A-state is being tracked (e.g., the A-state is not being tracked), then the DDL latch is left at “1”. Note that the DDL latch should be at “1” when a storage element passed the nominal verify (e.g., VvA) in steps 1116-1118 because that storage element also should have passed verify low (e.g., VvAL) in steps 1112-1114. Note that setting the DDL latch appropriately in step 1112 allows information to be maintained as to the intended program state for one of the states.

Note that the state to be tracked may also include the erase state. Note that there is not a verify operation for storage elements that are to stay in the erase state. Therefore, for these storage elements the status of the DDL latch should not change at step 1114. When a state other than the erase state is being tracked, the DDL latch for storage elements to remain erased may be initially set to “1”. However, when the erase state is being tracked, the DDL latch may be initially set to “0”. Therefore, it should remain at “0” throughout programming. In contrast, the DDL latch for other states may be set to “1” when verify low passes.

In step 1124, a determination is made whether there are additional states to verify. Note that early in the programming operation, it is not required that all states be verified. If there are more states to verify, then the verify reference voltage is increased in step 1126. The reference voltage may be increased to the verify low reference level for the next state. Then, the verify low pulse may be applied in step 1110. When all states that are to be verified at this time are verified, a determination is made whether all storage elements passed verify, in step 1128. Note that a certain number of storage elements may fail to reach their intended state, but be ignored. This can help to speed up programming.

If not all storage element pass verify (factored in that some may be allowed to fail), then the process 1100 returns to step 1106 to apply programming conditions based on the latches 394. For storage elements that are now locked out (as indicated by one or more of latches ADL, BDL, CDL), their bit lines may be set to Vdd. For storage elements to receive slow programming, their bit lines may be set to the intermediate voltage. In one embodiment, the DDL latch of those storage elements that are not locked out from further programming is checked to determine whether slow programming should be performed.

FIG. 12 is a flowchart of one embodiment of a process 1200 of operating data latches while programming and verifying non-volatile storage. Process 1200 provides further details of using the data latches differently depending on the stage of the programming process. FIG. 13A-FIG. 13D are tables that show status of data latches ADL, BDL, CDL, and DDL throughout various stages of process 1200.

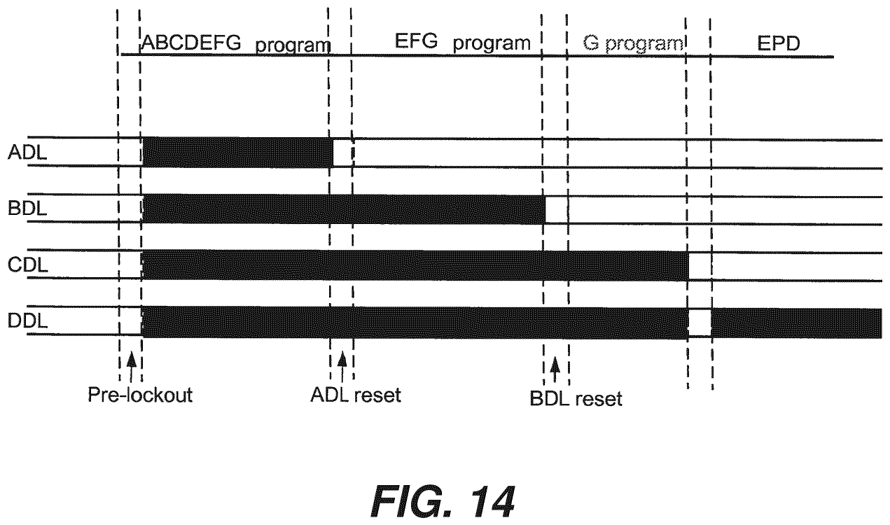

FIG. 14 shows latch usage during various stages of one embodiment of programming. Briefly, the programming process may be divided between the following stages. In the pre-lockout stage, data latches may be set up. In the ABCDEFG stage, all states are being programmed. In the EFG stage, only the E-, F-, and G-states are being programmed. In the G-program stage, only the G-state is being programmed. In the EPD-stage, erratic program detection is being performed. In one embodiment, word line defects are detected during the EPD stage. Note also that the ADL latches are reset between the ABCDEFG stage and the EFG stage. Likewise, the BDL latches are reset between the EFG stage and the G stage. Further details are discussed in connection with the discussion of FIG. 12.

Process 1200 describes one embodiment in which the G-state is the tracked state. In step 1202, the target data states are stored in latches. FIG. 13A shows a table of initial states for latches ADL, BDL, and CDL.

In step 1204, the initial state of the DDL latches are set. In this embodiment, the initial state for storage elements to remain in the erased state is set to “1.” The DDL for all other storage elements is set to “0.” FIG. 13A shows a table of initial states of the DDL latches for memory cells targeted for various states. Steps 1202 and 1204 may occur during the pre-lockout stage (see FIG. 14).

In step 1206, one or more programming pulses are applied, followed by verifying one or more states. One embodiment of step 1206 includes performing steps 1108, 1110, 1112, 1116, and 1118 of FIG. 11 one or more times. For example, step 1108 might be performed once, followed by steps 1110, 1112, 1116, and 1118 to verify different states.

Initially, the programming starts in the ABCDEFG stage (see FIG. 14). The black bars in FIG. 14 indicate when a data latch is actively being used for programming or EPD. During the ABCDEFG stage, the ADL, BDL, and CDL latches are being used to store lockout information. The DDL latches are being used to store QPW status.

FIG. 13B shows an example of use of the latches during the ABCDEFG stage. At this time, any storage element that is locked out has a “1” in all of the ADL, BDL, and CDL latches. The erase case is shown in this state. For states A-G, the data to be programmed into the storage element is shown. However, when a storage element reaches its intended target state, its ADL, BDL, and CDL latches maybe set to “1”. This was previously discussed as one possibility in step 1120 of FIG. 11. Thus, when determining whether a storage element is locked out during the ABCDEFG stage, the status of the ADL, BDL, and CDL may be checked.

FIG. 13B also shows an example of use of the DDL latches during the ABCDEFG stage. In one embodiment, a “1” in the DDL latch means that slow programming is to be used. Thus, any storage element that is not locked out, and that has a “1” in the DDL latch may receive slow programming.

Note that the DDL latch is being used differently for the G-state. For storage elements to be programmed to the G-state, the DDL latch is kept at “0” throughout the programming process, in one embodiment.

In step 1208, a determination is made whether storage elements targeted for states A-D are programmed. Note that it is not required that every storage element targeted for these states reaches its intended state. In one embodiment, some storage elements may be left under-programmed. If programming of the A-D states is not yet complete, the process returns to step 1206.

When storage elements targeted for states A-D are programmed, the ADL latches are freed up, in step 1210. This is reflected by the ADL reset in FIG. 14 after the ABCDEFG program stage. Referring to FIG. 13C, the ADL latches are free at this time. Because the ADL latches are free, they may be used for background caching, as one example. Further details of using data latches that are freed up during a program operation are described in U.S. Pat. No. 7,502,260, entitled “Method for Non-Volatile Memory with Background Data Latch Caching Operations During Program Operations, to Li et al., which is hereby incorporated in its entirety for all purposes.

Note that after the ADL latches are freed up, programming proceeds with the EFG program stage (see FIG. 14). At this time, only the BDL and CDL latches are used to store the lockout information, in one embodiment. Also, only the BDL and CDL latches are needed to contain the information needed to uniquely define which state a storage element is being programmed to. For example, the combination “01” uniquely defines the E-state, the combination “10” uniquely defines the F-state, the combination “00” uniquely defines the G-state, the combination “11” uniquely defines the lockout state, in one embodiment. Other bit assignments may be used.

Further, note that in FIG. 13C, the DDL latches of all storage elements below the E-state should be at “1”. Storage elements being programmed to either the E-state or F-state could have either a “1” or “0” in the DDL latch, depending on whether verify low has passed. As before, the DDL latch for the G-state storage elements remains at “0”. In one embodiment, no verify low is performed of the G-state storage elements. Therefore, the DDL latch should state “0” throughout programming. However, a verify low could be performed of the G-state, so long as the DDL latch is set to “0” when the storage element is locked out, as one example.

Next, programming continues with the EFG-stage (see FIG. 14). When determining how to apply programming conditions (step 1211 of FIG. 12), the status of the BDL and CDL latches may be used for lockout. Storage elements that are not locked out, and that have a “1” in the DDL latch may receive slow programming.

In step 1212, a determination is made whether the E and F states are programmed. If not the process continues to program and verify, using the status of latches BDL, CDL, and DDL.

When the E- and F-states are programmed, the BDL latches are freed up in step 1214. This is reflected by BDL reset at the end of the EFG program stage (see FIG. 14). As with the ADL latch, the BDL latch is free for purposes such as background caching.

FIG. 13D shows a table that represents the BDL latches being freed up. At this time, the only storage elements left to be programmed are those in the G-state. Therefore, the status of the CDL latch may uniquely describe whether a storage element is to be programmed to the G-state (“0” in this example) or is locked out (“1” in this example).

Note that the status of the DDL latch is “0” for G-state storage elements at this time. As was previously noted, the DDL latch may stay at “0” for the G-state storage elements throughout programming.

Programming then continues with the G-program stage (see, FIG. 14). In step 1215, program conditions are applied based on the status of CDL and DDL. The status of the CDL latch may be used to determine which storage elements are locked out. The status of the DDL latch remains “0” for all G-state storage elements in one embodiment. However, in one embodiment, the DDL latch may be used for QPW status. Therefore, if this is the case, then storage elements that are not locked out and have the DDL latch set to “1” may receive slow programming.

When the G-state storage elements are programmed (step 1216), the G-program stage is over. At this time, the CDL latch for all G-state storage elements should be “1”. The DDL latch for all G-state storage elements should be “0”. Note that in one embodiment, the DDL latch is “0” because it is not allowed to be set to “1” during the programming operation.

However, in one embodiment, the DDL latch is permitted to be set to “1” when the G-state storage element passes verify low. In this case, the DDL latch may be set to “0” when the G-state storage element passes verify high.

Regardless of whether the information from the DDL latch is kept in that latch, transferred to another latch, or some other storage location, the information of which storage elements were targeted for the G-state is maintained after the programming operation. Note that no extra data latches are needed. Also note that two of the data latches are freed up during programming for purposes such as background caching.

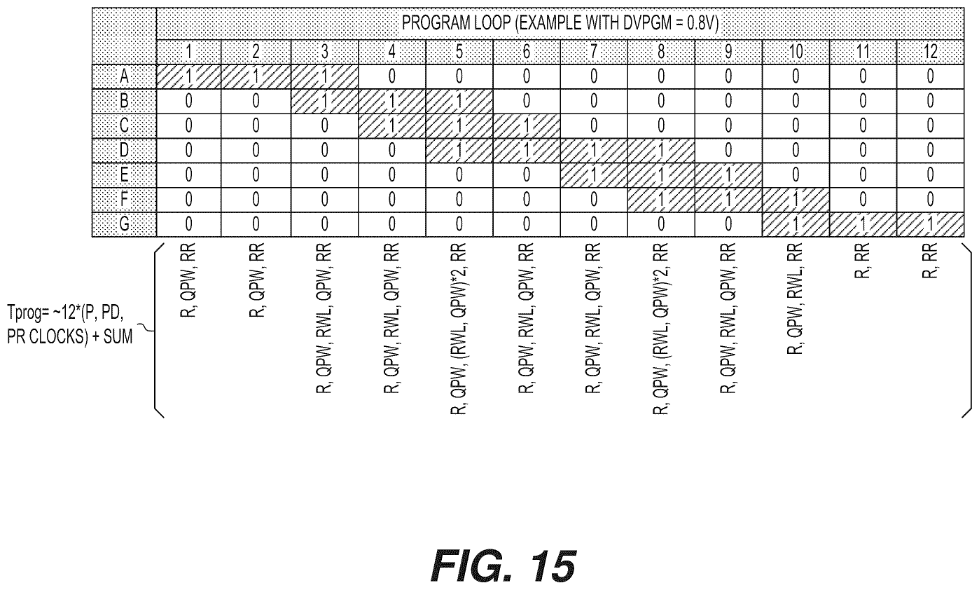

As discussed above, when every data state is verified, significant programming time is consumed. Specifically, programming operations for triple level cells (TLC) may involve application of a program pulse followed by a verify iteration or program-verify (pvfy) for each data state and repeats until most of the memory cells have passed their respective program verify voltage or level (with an acceptable amount of slow cells, set by parameter). FIG. 15 is a table showing the number of program loops and verify iterations (shaded) for each data state in a program operation for triple level cells (TLC) along with time periods included in each of the program loops. As shown, program time tPROG is predominantly composed of the program pulse (P, PD, PR clocks or time periods) and verification time for each state (R, QPW, RWL, QPW, RR clocks or time periods). Algorithms have been developed to optimize the number of verify iterations required for each state (e.g., Smart PCV) and fine tune ideal starting program voltage VPGM for optimized program pulses (e.g., Smart verify). However, it would be desirable to somehow reduce the program time tPROG required in verifying the memory cells targeted for every data state.

Consequently, described herein is a memory apparatus (e.g., non-volatile storage device 210 of FIG. 2) including memory cells (e.g., transistors, 100, 102, 104 and 106 of FIG. 1B) each connected to one of a plurality of word lines (e.g., word lines WL3, WL2, WL1 and WL0 of FIG. 1B or WL0-WL63 of FIG. 4). The memory cells are configured to retain a threshold voltage Vt or Vth corresponding to one of a plurality of memory or data states (e.g., FIGS. 5 and 6). The plurality of data states including a highest data state (e.g., data state G in FIGS. 5 and 6) in which the threshold voltage of the memory cells associated therewith is higher than for others of the plurality of data states (e.g., erase state and A-F data states of FIGS. 5 and 6). The memory apparatus also includes a control circuit or means (e.g., one or any combination of control circuitry 220, decoders 240A, 240B, 242A and 242B, power control module 226, sense blocks 300, read/write circuits 230A and 230B, controller 244 of FIG. 2 and so forth). The control means is configured to apply each of a series of programming pulses of a program voltage followed by verification pulses of a plurality of program verify voltages each associated with one of the plurality of data states to selected ones of the plurality of word lines to program and verify the memory cells connected thereto during each of a plurality of program loops of a program operation. The control means is also configured to skip verification of the memory cells targeted for the highest data state in at least one of the plurality of program loops. Thus, by eliminating/reducing the verification of the memory cells targeted for the highest data state (e.g., data state G in FIGS. 5 and 6) and controlling the programming of the memory cells targeted for the highest data state via program loop count and/or bit line bias only, as will be detailed below, the program time tPROG may be further reduced. The highest data state is selected, since it can tolerate a wider threshold voltage distribution as long as it is not impacting the read pass voltage VREAD needed.

According to an aspect, the program-verify of the highest data state (e.g., data state G) may be skipped completely and data latches can be used to track the loop counts, such an approach will be referred to herein as option one. As discussed above, the memory cells may be disposed in memory holes (e.g., NAND strings of FIG. 4) each coupled to one of a plurality of bit lines (e.g., bit lines BL0-BL13 of FIG. 4). Furthermore, the memory apparatus can further includes a plurality of data latches (e.g., data latches 394, 395, 396, 397 of FIG. 3) each configured to store data to be programmed during the program operation and control the one of the plurality of bit lines to allow or inhibit programming of the memory cells of the memory holes coupled to the one of the plurality of bit lines. The plurality of data latches each store one bit to define bit combinations. Thus, the control means can be further configured to operate and update the plurality of data latches based on the data being programmed to the memory cells and the threshold voltage of the memory cells and which of the plurality of data states is being programmed and verified during the program operation. The control means is also configured to update the plurality of data latches to track a quantity of subsequent ones of the plurality of program loops for each of the memory cells targeted to be programmed to the highest data state using one or more of the bit combinations.

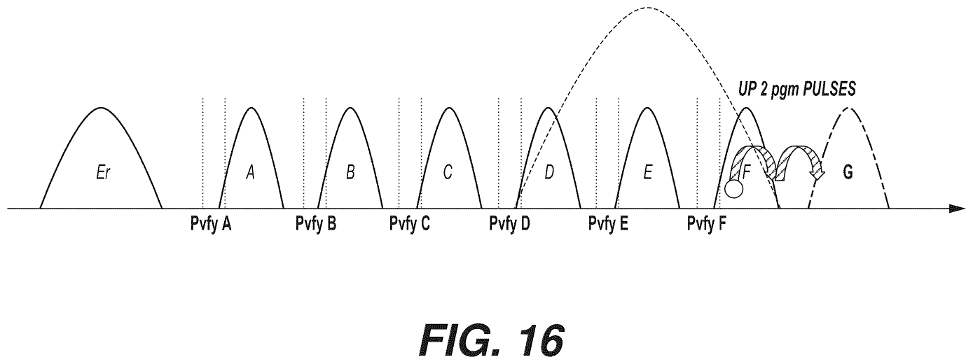

FIG. 16 is a plot of threshold voltage distributions when the program-verify of the highest data state is skipped completely. As shown the erase state or Er (inhibit) and A-F states program-verify and lockout as normal. For G state cells upon passing pvfy F level (i.e., the program verify voltage for the data state F), count program loops till lockout (inhibit). The G state cells are tracked cell by cell. As discussed, each of the memory cells can configured to store three bits. Thus, continuing to refer to FIG. 16, for example, and the plurality of data states can include, in order of the threshold voltage increasing in magnitude, an erased data state (Er) and a first data state (A) and a second data state (B) and a third data state (C) and a fourth data state (D) and a fifth data state (E) and a sixth data state (F) and a seventh data state (G). Accordingly, the highest data state is the seventh data state. So according to another aspect, the plurality of data latches includes a first data latch ADL, a second data latch BDL, and a third data latch CDL each configured to store data to be programmed during the program operation. The plurality of data latches can also include a fourth data latch DDL configured to control the one of the plurality of bit lines to allow or inhibit programming of the memory cells of the memory holes coupled to the one of the plurality of bit lines. The bit combinations include sixteen bit combinations.

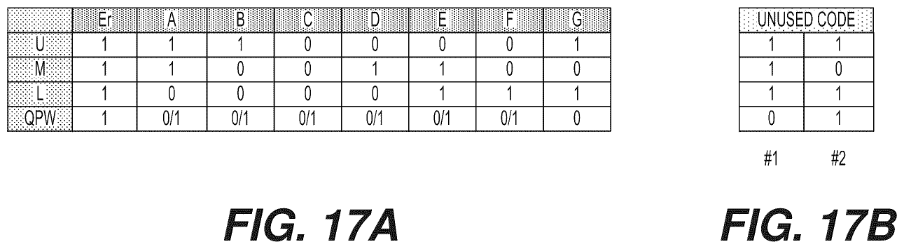

FIG. 17A is a table illustrating information stored in the first data latch ADL (L), the second data latch BDL (M), the third data latch CDL (U), and the fourth data latch DDL(QPW) for each data state for triple-level memory cells. As shown, fourteen bit combinations are necessary to differentiate, twelve are needed for A to F states fast program (bit line set to a steady state voltage VSS) and QPW program (bit line set to VBLC_QPW), one is needed for the inhibit case Er or passed program verify high VH case, and one is needed for one G-state case (no QPW). However, because the four data latches ADL, BDL, CDL, DDL can represent sixteen bit combinations, that leaves two unused bit or code combinations. FIG. 17B is a table illustrating unused ones of the bit combinations of bits in the first data latch ADL (L), the second data latch BDL (M), the third data latch CDL (U), and the fourth data latch DDL(QPW). These unused bit combinations can be used for tracking the highest data state (e.g., G-state) memory cells after passing the verify voltage level for the next highest data state (data state F) for option one. No change is necessary to the XDL latch (user cache) limits. Thus, the control means is further configured to update at least one of the first data latch ADL and the second data latch BDL and the third data latch CDL and the fourth data latch DDL associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state. The control means is additionally configured to update at least one of the first data latch ADL and the second data latch BDL and the third data latch CDL and the fourth data latch DDL associated with the one of the memory cells targeted for the seventh data state from the first unused one of the sixteen bit combinations to a second unused one of the sixteen bit combinations following application of a first subsequent one of the series of programming pulses of the program voltage to the one of the memory cells targeted for the seventh data state. The control means is also configured to update at least one of the first data latch ADL and the second data latch BDL and the third data latch CDL and the fourth data latch DDL associated with the one of the memory cells targeted for the seventh data state from the second unused one of the sixteen bit combinations to one of the sixteen bit combinations associated with the erased data state to inhibit programming of the one of the memory cells targeted for the seventh data state following application of a second subsequent one of the series of programming pulses of the program voltage to the one of the memory cells targeted for the seventh data state.

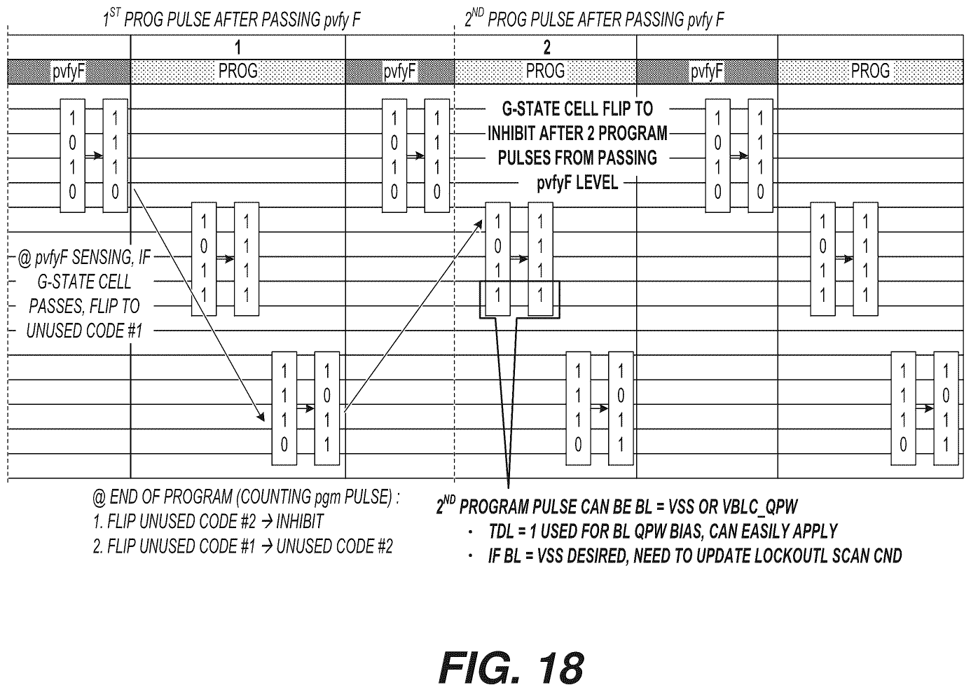

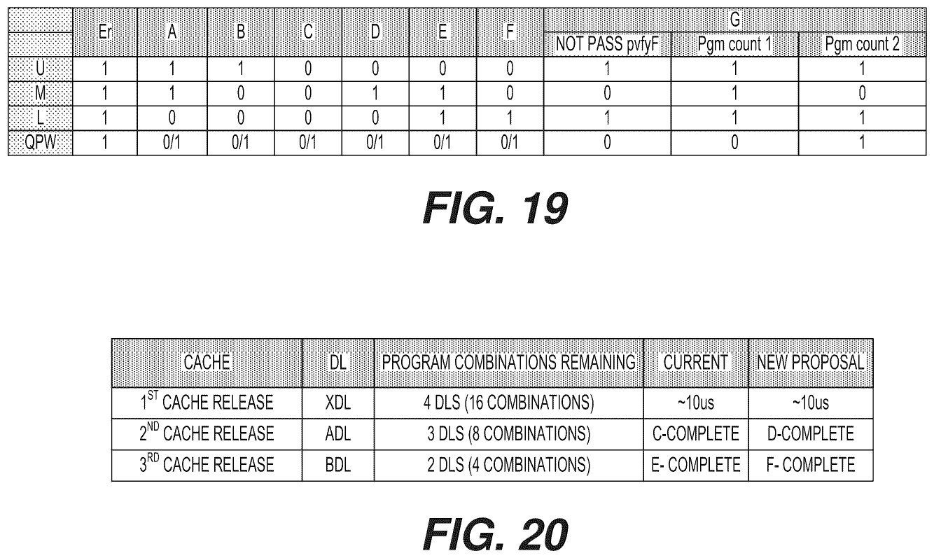

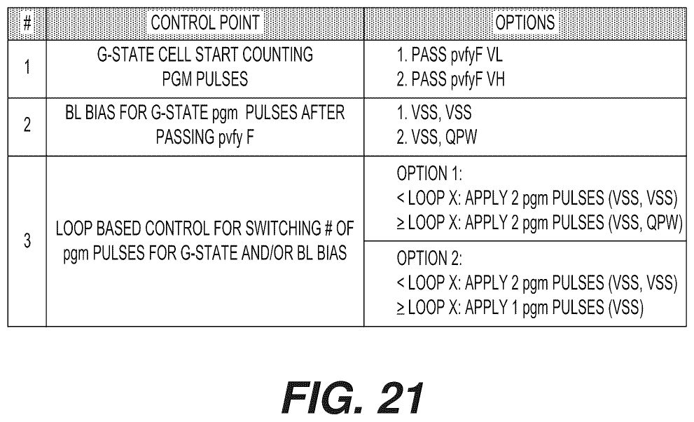

FIG. 18 is a diagram illustrating example tracking of the memory cells targeted for the highest data state through subsequent ones of the plurality of program loops using the two unused bit combinations for option one. FIG. 19 is another table illustrating information stored in the first data latch ADL (L), the second data latch BDL (M), the third data latch CDL (U), and the fourth data latch DDL(QPW) for each data state for option one. FIG. 20 is a table illustrating an impact to the cache releases (i.e., at which of the plurality of program loops data latches can be released to allow the user data for a next page to be stored). In memory apparatuses not employing option one, the G-state does not support QPW and only uses one bit combination, however, as discussed, option one G-state uses three combinations of code, hence a delay in internal cache release may be needed. FIG. 21 summarizes variations of parameters affecting operation of the memory apparatus using option one. As shown, beyond two program pulses for G-state can still be implemented by using XDL (fifth data latch) for TLC. Such an approach will have impact on user cache release and cause a delay for internal second and third bit cache release.

Instead of skipping program-verify of the highest data state (e.g., G state) completely, the memory apparatus may only skip program-verify of the highest data state after the next highest data state (e.g., F-state) complete. Such an approach will be referred to herein as option two. In option two, a counter can be used to track program loops. As discussed, referring back to FIG. 16, for example, the plurality of data states can include, in order of the threshold voltage increasing in magnitude, an erased data state (Er), a next highest data state (F), and the highest data state (G). Thus, prior to the next highest data state completing verification (i.e., in response to a predetermined amount of the ones of the memory cells targeted for the next highest data state and the highest data state not having the threshold voltage greater than the one of the plurality of verify voltages associated with the next highest data state), the control means can be further configured to program and verify ones of the memory cells using the series of programming pulses of the program voltage followed by the verification pulses of the plurality of program verify voltages associated therewith and lockout the memory cells having the threshold voltage greater than one of the plurality of verify voltages of the one of the plurality of data states targeted from further programming. Following the next highest data state completing verification (i.e., in response to the predetermined amount of the ones of the memory cells targeted for the next highest data state and the highest data state having the threshold voltage greater than the one of the plurality of verify voltages associated with the next highest data state), the control means may be configured to stop further verification of the ones of the memory cells targeted for the highest data state and count subsequent ones of the plurality of program loops. The control means can also be configured to inhibit programming of the ones of the memory cells targeted for the highest data state in response to a quantity of the subsequent ones of the plurality of program loops exceeding a predetermined slow cell count threshold.

As discussed, each of the memory cells can be configured to store three bits. So, referring back to FIG. 16, for example, the plurality of data states includes, in order of the threshold voltage increasing in magnitude, the erased data state (Er) and a first data state (A) and a second data state (B) and a third data state (C) and a fourth data state (D) and a fifth data state (E) and a sixth data state (F) and a seventh data state (G). Thus, the next highest data state is the sixth data state (F) and the highest data state is the seventh data state (G). Accordingly, prior to the sixth data state completing verification, the control means can be further configured to program and verify ones of the memory cells targeted for the first data state and the second data state and the third data state and the fourth data state and the fifth data state and the sixth data state and the seventh data state using the series of programming pulses of the program voltage followed by the verification pulses of the plurality of program verify voltages associated therewith. The control means locks out the memory cells having the threshold voltage greater than one of the plurality of verify voltages of the one of the plurality of data states targeted from further programming in response to the ones of the memory cells targeted for the sixth data state and the seventh data state not having the threshold voltage greater than the one of the plurality of verify voltages associated with the sixth data state. Following the next highest data state completing verification, the control means may be configured to stop further verification of the ones of the memory cells targeted for the seventh data state and count subsequent ones of the plurality of program loops in response to the ones of the memory cells targeted for the sixth data state and the seventh data state having the threshold voltage greater than the one of the plurality of verify voltages associated with the sixth data state. The control means is also configured to inhibit programming of the ones of the memory cells targeted for the seventh data state in response to a quantity of the subsequent ones of the plurality of program loops exceeding the predetermined slow cell count threshold.

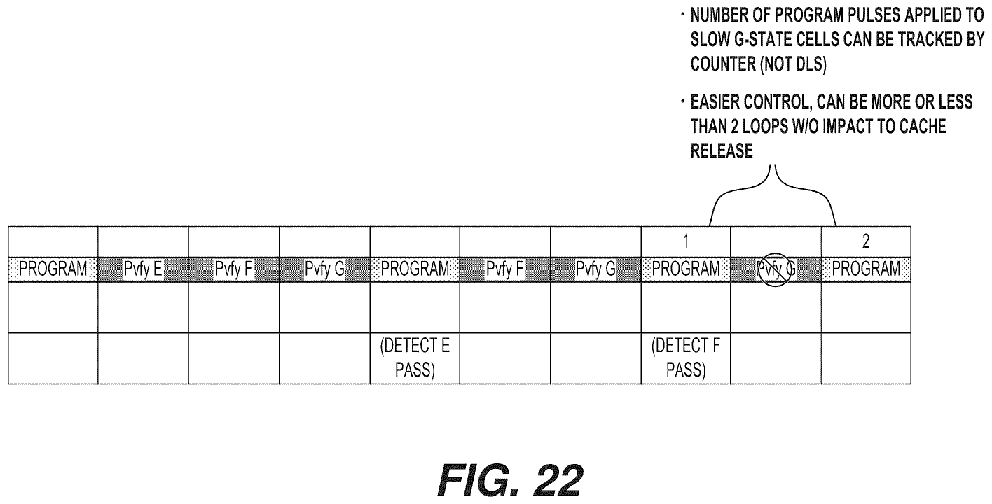

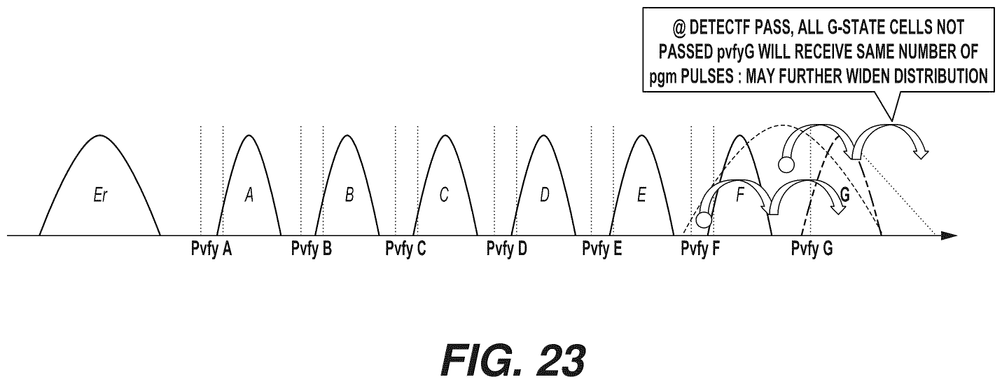

So, for option two, before F-state complete (e.g., fail data state F bitscan), Er state (inhibit) and A-G states program verify and lockout as normal. After F-state completes (pass data state F bitscan), no program verify is done. The remaining G-state slow cells count program loops until being locked out (inhibit) using a counter. FIG. 22 illustrates an example sequence of program loops for option two. As shown, a number of program pulses applied to slow G-state cells can be tracked by counter (not data latches). Such an approach provides easier control and can be more or less than two loops without impact to cache release. FIG. 23 is a plot of threshold voltage distributions when program-verify of the highest data state is skipped after the next highest data state (e.g., F-state) complete and using a counter to track program loops for slow cells targeted for the highest data state. As shown, after F-state completes (i.e., detectF pass), all G-state cells not passed G program verify will receive same number of program pulses, this may further widen the threshold voltage distribution for the highest data state.

According to another aspect, the memory apparatus may only skip program-verify of the highest data state (e.g., G-state) after the next highest data state (e.g., F-state) is complete, similar to option two, but using data latches to track program loop counts instead of a counter. Such an approach will be referred to herein as option three. For option three, prior to the next highest data state completing verification (i.e., in response to a predetermined amount of the ones of the memory cells targeted for the next highest data state and the highest data state not having the threshold voltage greater than the one of the plurality of verify voltages associated with the next highest data state), the control means is configured to program and verify ones of the memory cells using the series of programming pulses of the program voltage followed by the verification pulses of the plurality of program verify voltages associated therewith. The control means locks out the memory cells having the threshold voltage greater than one of the plurality of verify voltages of the one of the plurality of data states targeted from further programming. Following the next highest data state completing verification (i.e., in response to the predetermined amount of the ones of the memory cells targeted for the next highest data state and the highest data state having the threshold voltage greater than the one of the plurality of verify voltages associated with the next highest data state), the control means stops further verification of the ones of the memory cells targeted for the highest data state and update the plurality of data latches to track a quantity of subsequent ones of the plurality of program loops for each of the memory cells targeted to be programmed to the highest data state using one or more of the bit combinations.

In more detail, for option three, prior to the sixth data state completing verification (i.e., in response to a predetermined amount of the ones of the memory cells targeted for the sixth data state (e.g., data state F) and the seventh data state (e.g., data state G) not having the threshold voltage greater than the one of the plurality of verify voltages associated with the sixth data state), the control means is further configured to update at least one of the first data latch ADL and the second data latch BDL and the third data latch CDL and the fourth data latch DDL associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state. Prior to the sixth data state completing verification, the control means updates at least one of the first data latch ADL and the second data latch BDL and the third data latch CDL and the fourth data latch DDL associated with the one of the memory cells targeted for the seventh data state to one of the sixteen bit combinations associated with the erased data state to inhibit programming of the one of the memory cells targeted for the seventh data state in response to the one of the memory cells having the threshold voltage greater than the one of the plurality of program verify voltages associated with the seventh data state sensed during one of the verification pulses of the one of the plurality of program verify voltages associated with the seventh data state. Prior to the sixth data state completing verification, the control means updates at least one of the first data latch ADL and the second data latch BDL and the third data latch CDL and the fourth data latch DDL associated with the one of the memory cells targeted for the seventh data state from the first unused one of the sixteen bit combinations to a second unused one of the sixteen bit combinations following application of one of the series of programming pulses of the program voltage to the one of the memory cells targeted for the seventh data state. Following the sixth data state completing verification (i.e., in response to the predetermined amount of the ones of the memory cells targeted for the sixth data state and the seventh data state having the threshold voltage greater than the one of the plurality of verify voltages associated with the sixth data state), the control means updates at least one of the first data latch ADL and the second data latch BDL and the third data latch CDL and the fourth data latch DDL associated with the one of the memory cells targeted for the seventh data state from the first unused one of the sixteen bit combinations from the second unused one of the sixteen bit combinations to one of the sixteen bit combinations associated with the erased data state to inhibit programming of the one of the memory cells targeted for the seventh data state following application of a first subsequent one of the series of programming pulses of the program voltage to the one of the memory cells targeted for the seventh data state and in response to the one of the memory cells targeted for the seventh data state having the threshold voltage greater than the one of the plurality of verify voltages associated with the sixth data state and less than the one of the plurality of verify voltages associated with the seventh data state. Following the sixth data state completing verification, the control means updates at least one of the first data latch ADL and the second data latch BDL and the third data latch CDL and the fourth data latch DDL associated with the one of the memory cells targeted for the seventh data state from the first unused one of the sixteen bit combinations to a second unused one of the sixteen bit combinations following application of a second subsequent one of the series of programming pulses of the program voltage to the one of the memory cells targeted for the seventh data state and in response to the one of the memory cells targeted for the seventh data state having the threshold voltage greater than the one of the plurality of verify voltages associated with the sixth data state and less than the one of the plurality of verify voltages associated with the seventh data state.

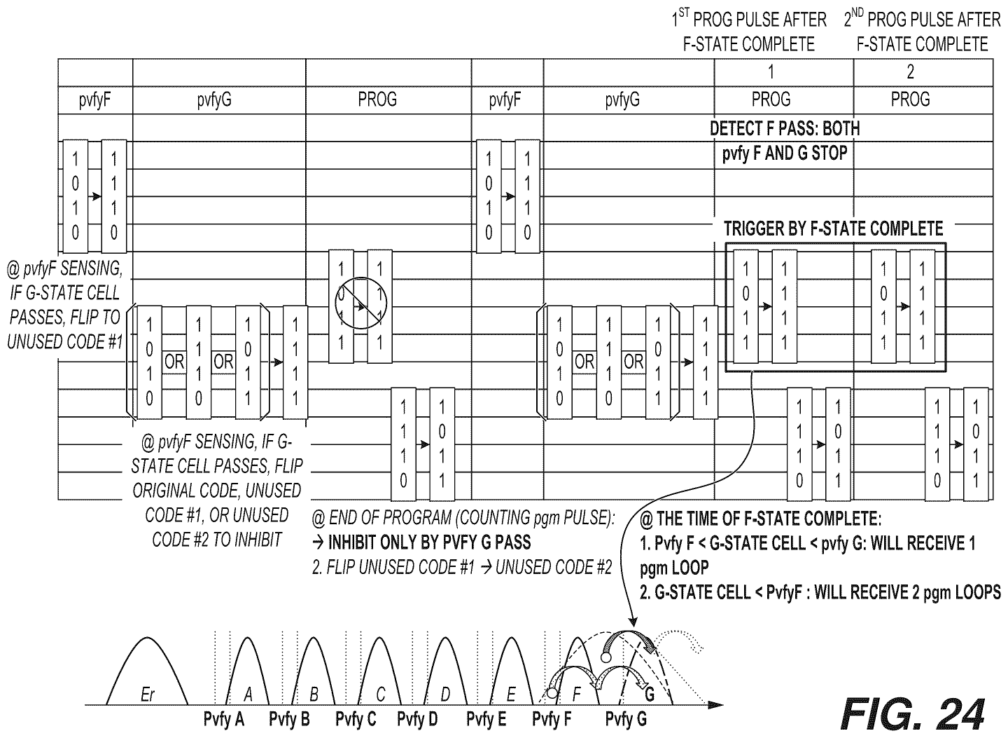

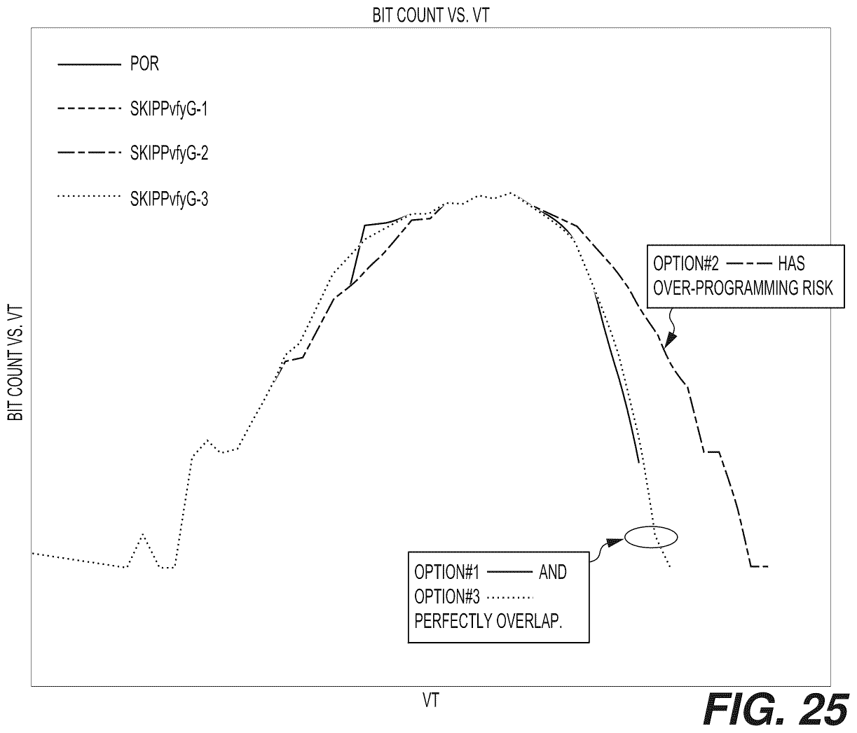

So, before F-state complete (fail data state F bitscan), Er (inhibit) and A-G states program-verify and lockout as normal. After F-state complete (pass data state F bitscan), no program verify is done. The remaining G-state slow cells count program loops until lockout (inhibit) by tracking each individual slow cell loop count using the data latches. The program time tPROG savings is the same as option two, but 3-bit cache impact same as option one. FIG. 24 is a diagram illustrating example tracking of the memory cells along with a corresponding plot of threshold voltage distributions for option three. FIG. 25 shows simulation results for options one, two and three compared to no skipping of the program verify for the highest data state (POR). Specifically, to evaluate the impact from the three options, individual cell threshold voltage Vt data versus program pulse (without any QPW-programming) data is collected. Then using this data, the options are simulated. The G-state threshold voltage Vt distribution is shown in FIG. 25. As shown, options one and three are identical and very similar to POR. Option two has an over-programming risk. Option one achieves the fastest program time tPROG and also maintains very good threshold voltage Vt-distribution. Option two has a simpler implementation (eliminating the need for data latch loop tracking), but in exchange has over-programming risk. Option three at least in this simulation shows no benefit compared to option one, and also has less program time tPROG improvement. Options three and one have the same lower tails of the threshold voltage distributions, implying a small risk for cells that may require more than two pulses after passing F-verify. Options three and one have the same upper tails, implying small risk for cells that may require only one extra pulse after passing F-verify.

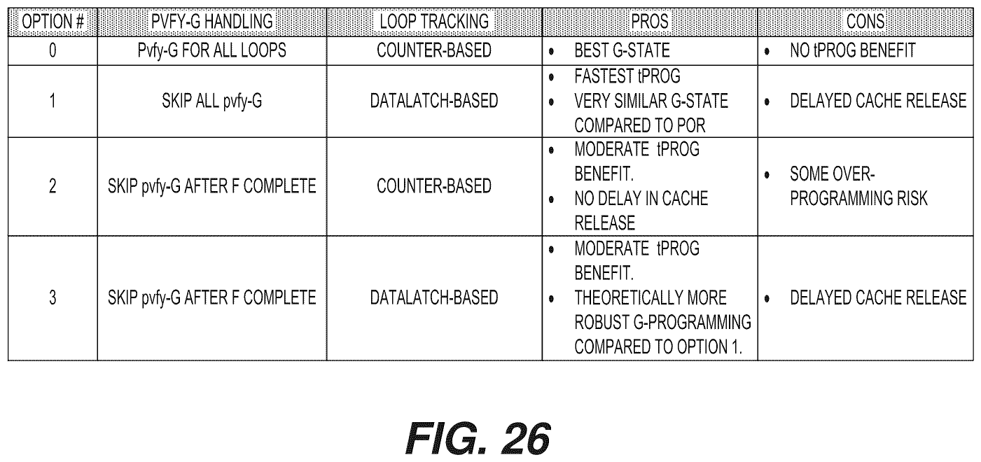

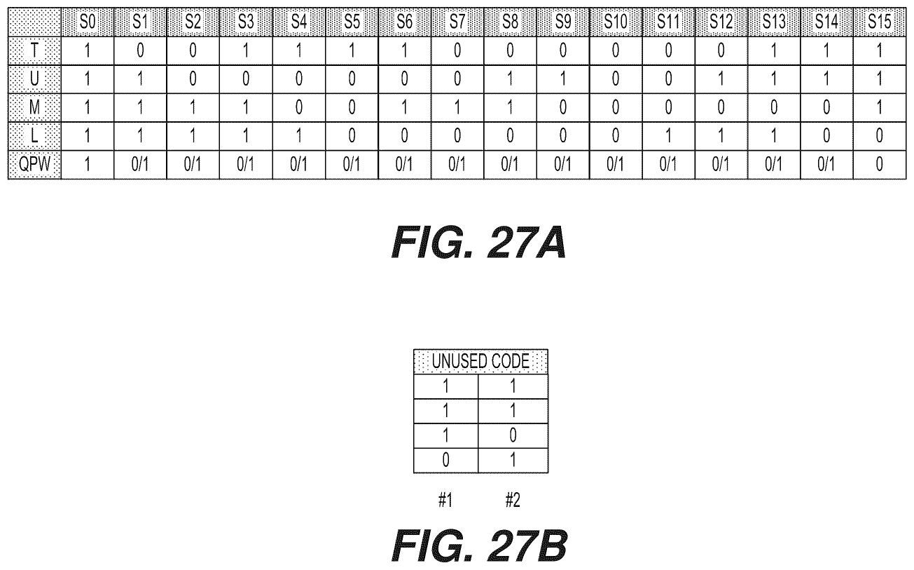

FIG. 26 is a comparison of no skipping of the program verify for the highest data state, option one, option two, and option three. All 3 options can be applied to four-level cell (QLC) memory apparatuses as well for program verify S15 savings. FIG. 27A is a table illustrating information stored in the first data latch ADL (L), the second data latch BDL (M), the third data latch CDL (U), and a different fourth data latch (T) and a fifth data latch DDL(QPW) for each data state for four-level memory cells (QLC). As shown, thirty bit combinations are necessary to differentiate, twenty eight are needed for S1-S14 states fast program (bit line set to a steady state voltage VSS) and QPW program (bit line set to VBLC_QPW), one is needed for the inhibit case (Er or passed program verify high VH), and one is needed for one S15 state case (no QPW). Nevertheless, because the five data latches can represent thirty two bit combinations, that leaves two unused bit or code combinations. FIG. 27B is a table illustrating unused ones of the bit combinations of bits in the first data latch ADL (L), the second data latch BDL (M), the third data latch CDL (U), and the different fourth data latch (T) and fifth data latch DDL(QPW). Again, there is no change to XDL (user cache) limits, but will have a delay for internal 2^{nd} and 3^{rd} bit cache release.

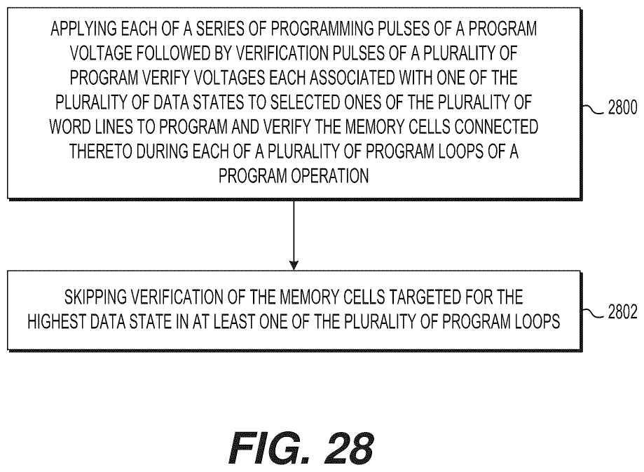

FIG. 28 illustrates steps of a method of operating a memory apparatus (e.g., non-volatile storage device 210 of FIG. 2). As discussed above, the memory apparatus includes memory cells (e.g., transistors, 100, 102, 104 and 106 of FIG. 1B) each connected to one of a plurality of word lines (e.g., word lines WL3, WL2, WL1 and WL0 of FIG. 1B or WL0-WL63 of FIG. 4). The memory cells are configured to retain a threshold voltage Vt or Vth corresponding to one of a plurality of memory or data states (e.g., FIGS. 5 and 6). The plurality of data states including a highest data state (e.g., data state G in FIGS. 5 and 6) in which the threshold voltage of the memory cells associated therewith is higher than for others of the plurality of data states (e.g., erase state and A-F data states of FIGS. 5 and 6). The method includes the step of 2800 applying each of a series of programming pulses of a program voltage followed by verification pulses of a plurality of program verify voltages each associated with one of the plurality of data states to selected ones of the plurality of word lines to program and verify the memory cells connected thereto during each of a plurality of program loops of a program operation. The method also includes the step of 2802 skipping verification of the memory cells targeted for the highest data state in at least one of the plurality of program loops.

Again, according to an aspect, the program-verify of the highest data state (e.g., data state G) may be skipped completely and data latches can be used to track the loop counts for option one. As above, the memory cells may be disposed in memory holes (e.g., NAND strings of FIG. 4) each coupled to one of a plurality of bit lines (e.g., bit lines BL0-BL13 of FIG. 4). In addition, the memory apparatus can further includes a plurality of data latches (e.g., data latches 394, 395, 396, 397 of FIG. 3) each configured to store data to be programmed during the program operation and control the one of the plurality of bit lines to allow or inhibit programming of the memory cells of the memory holes coupled to the one of the plurality of bit lines. The plurality of data latches each store one bit to define bit combinations. Therefore, the method can further include the step of operating and updating the plurality of data latches based on the data being programmed to the memory cells and the threshold voltage of the memory cells and which of the plurality of data states is being programmed and verified during the program operation. The method also may include the step of updating the plurality of data latches to track a quantity of subsequent ones of the plurality of program loops for each of the memory cells targeted to be programmed to the highest data state using one or more of the bit combinations.

Referring back to FIG. 16, for example, the plurality of data states can include, in order of the threshold voltage increasing in magnitude, an erased data state (Er) and a first data state (A) and a second data state (B) and a third data state (C) and a fourth data state (D) and a fifth data state (E) and a sixth data state (F) and a seventh data state (G). Thus, the highest data state is the seventh data state. According to another aspect, the plurality of data latches includes a first data latch ADL, a second data latch BDL, and a third data latch CDL each configured to store data to be programmed during the program operation. The plurality of data latches can also include a fourth data latch DDL configured to control the one of the plurality of bit lines to allow or inhibit programming of the memory cells of the memory holes coupled to the one of the plurality of bit lines. The bit combinations include sixteen bit combinations.

As discussed above with reference to FIGS. 17A and 17B, two unused bit or code combinations exist when using the four data latches. Therefore, the method can further include the step of updating at least one of the first data latch ADL and the second data latch BDL and the third data latch CDL and the fourth data latch DDL associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state. In addition, the method can include updating at least one of the first data latch ADL and the second data latch BDL and the third data latch CDL and the fourth data latch DDL associated with the one of the memory cells targeted for the seventh data state from the first unused one of the sixteen bit combinations to a second unused one of the sixteen bit combinations following application of a first subsequent one of the series of programming pulses of the program voltage to the one of the memory cells targeted for the seventh data state. Additionally, the method can also include the step of updating at least one of the first data latch ADL and the second data latch BDL and the third data latch CDL and the fourth data latch DDL associated with the one of the memory cells targeted for the seventh data state from the second unused one of the sixteen bit combinations to one of the sixteen bit combinations associated with the erased data state to inhibit programming of the one of the memory cells targeted for the seventh data state following application of a second subsequent one of the series of programming pulses of the program voltage to the one of the memory cells targeted for the seventh data state.

Again, instead of skipping program-verify of the highest data state (e.g., G state) completely, the memory apparatus may only skip program-verify of the highest data state after the next highest data state (e.g., F-state) complete for option two. So, referring back to FIG. 16, for example, the plurality of data states can include, in order of the threshold voltage increasing in magnitude, an erased data state (Er), a next highest data state (F), and the highest data state (G). Therefore, the method may further include the step of prior to the next highest data state completing verification, programming and verifying ones of the memory cells using the series of programming pulses of the program voltage followed by the verification pulses of the plurality of program verify voltages associated therewith and locking out the memory cells having the threshold voltage greater than one of the plurality of verify voltages of the one of the plurality of data states targeted from further programming. In addition, following the next highest data state completing verification, stopping further verification of the ones of the memory cells targeted for the highest data state and counting subsequent ones of the plurality of program loops. The method can also include the step of inhibiting programming of the ones of the memory cells targeted for the highest data state in response to a quantity of the subsequent ones of the plurality of program loops exceeding a predetermined slow cell count threshold.

Once again, referring back to FIG. 16, for example, the plurality of data states includes, in order of the threshold voltage increasing in magnitude, the erased data state (Er) and a first data state (A) and a second data state (B) and a third data state (C) and a fourth data state (D) and a fifth data state (E) and a sixth data state (F) and a seventh data state (G). Accordingly, the next highest data state is the sixth data state (F) and the highest data state is the seventh data state (G). So, the method can further include the step of prior to the sixth data state completing verification, programming and verifying ones of the memory cells targeted for the first data state and the second data state and the third data state and the fourth data state and the fifth data state and the sixth data state and the seventh data state using the series of programming pulses of the program voltage followed by the verification pulses of the plurality of program verify voltages associated therewith and locking out the memory cells having the threshold voltage greater than one of the plurality of verify voltages of the one of the plurality of data states targeted from further programming in response to the ones of the memory cells targeted for the sixth data state and the seventh data state not having the threshold voltage greater than the one of the plurality of verify voltages associated with the sixth data state. The method may additionally include the step of following the next highest data state completing verification, stopping further verification of the ones of the memory cells targeted for the seventh data state and counting subsequent ones of the plurality of program loops in response to the ones of the memory cells targeted for the sixth data state and the seventh data state having the threshold voltage greater than the one of the plurality of verify voltages associated with the sixth data state. The method can also include inhibiting programming of the ones of the memory cells targeted for the seventh data state in response to a quantity of the subsequent ones of the plurality of program loops exceeding the predetermined slow cell count threshold.

Again, according to another aspect, the memory apparatus may only skip program-verify of the highest data state (e.g., G-state) after the next highest data state (e.g., F-state) is complete, similar to option two, but using data latches to track program loop counts instead of a counter for option three. For option three, the method can include the step of prior to the next highest data state completing verification, programming and verifying ones of the memory cells using the series of programming pulses of the program voltage followed by the verification pulses of the plurality of program verify voltages associated therewith and locking out the memory cells having the threshold voltage greater than one of the plurality of verify voltages of the one of the plurality of data states targeted from further programming. The method can also include the step of following the next highest data state completing verification, stopping further verification of the ones of the memory cells targeted for the highest data state and updating the plurality of data latches to track a quantity of subsequent ones of the plurality of program loops for each of the memory cells targeted to be programmed to the highest data state using one or more of the bit combinations.

For option three, the method can further include the step of prior to the sixth data state completing verification, updating at least one of the first data latch ADL and the second data latch BDL and the third data latch CDL and the fourth data latch DDL associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state. The method can additionally include the step of prior to the sixth data state completing verification, updating at least one of the first data latch ADL and the second data latch BDL and the third data latch CDL and the fourth data latch DDL associated with the one of the memory cells targeted for the seventh data state to one of the sixteen bit combinations associated with the erased data state to inhibit programming of the one of the memory cells targeted for the seventh data state in response to the one of the memory cells having the threshold voltage greater than the one of the plurality of program verify voltages associated with the seventh data state sensed during one of the verification pulses of the one of the plurality of program verify voltages associated with the seventh data state. Further, the method may include the step of prior to the sixth data state completing verification, updating at least one of the first data latch ADL and the second data latch BDL and the third data latch CDL and the fourth data latch DDL associated with the one of the memory cells targeted for the seventh data state from the first unused one of the sixteen bit combinations to a second unused one of the sixteen bit combinations following application of one of the series of programming pulses of the program voltage to the one of the memory cells targeted for the seventh data state. The method can also include the step of following the sixth data state completing verification, updating at least one of the first data latch ADL and the second data latch BDL and the third data latch CDL and the fourth data latch DDL associated with the one of the memory cells targeted for the seventh data state from the first unused one of the sixteen bit combinations from the second unused one of the sixteen bit combinations to one of the sixteen bit combinations associated with the erased data state to inhibit programming of the one of the memory cells targeted for the seventh data state following application of a first subsequent one of the series of programming pulses of the program voltage to the one of the memory cells targeted for the seventh data state and in response to the one of the memory cells targeted for the seventh data state having the threshold voltage greater than the one of the plurality of verify voltages associated with the sixth data state and less than the one of the plurality of verify voltages associated with the seventh data state. In addition, the method may include the step of following the sixth data state completing verification, updating at least one of the first data latch ADL and the second data latch BDL and the third data latch CDL and the fourth data latch DDL associated with the one of the memory cells targeted for the seventh data state from the first unused one of the sixteen bit combinations to a second unused one of the sixteen bit combinations following application of a second subsequent one of the series of programming pulses of the program voltage to the one of the memory cells targeted for the seventh data state and in response to the one of the memory cells targeted for the seventh data state having the threshold voltage greater than the one of the plurality of verify voltages associated with the sixth data state and less than the one of the plurality of verify voltages associated with the seventh data state.

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections.

Additionally, when a layer or element is referred to as being “on” another layer or substrate, in can be directly on the other layer of substrate, or intervening layers may also be present. Further, it will be understood that when a layer is referred to as being “under” another layer, it can be directly under, and one or more intervening layers may also be present. Furthermore, when a layer is referred to as “between” two layers, it can be the only layer between the two layers, or one or more intervening layers may also be present.

As described herein, a controller includes individual circuit components, an application-specific integrated circuit (ASIC), a microcontroller with controlling software, a digital signal processor (DSP), a processor with controlling software, a field programmable gate array (FPGA), or combinations thereof.

What is claimed is:

1. A memory apparatus, comprising:
memory cells each connected to one of a plurality of word lines and configured to retain a threshold voltage corresponding to one of a plurality of data states, the plurality of data states including a highest data state in which the threshold voltage of the memory cells associated therewith is higher than for others of the plurality of data states; and
a control means configured to:
apply each of a series of programming pulses of a program voltage followed by verification pulses of a plurality of program verify voltages each associated with one of the plurality of data states to selected ones of the plurality of word lines to program and verify the memory cells connected thereto during each of a plurality of program loops of a program operation, and
skip verification of the memory cells targeted for the highest data state in at least one of the plurality of program loops.

2. The memory apparatus as set forth in claim 1, wherein the memory cells are disposed in memory holes each coupled to one of a plurality of bit lines, the memory apparatus further includes a plurality of data latches each configured to store data to be programmed during the program operation and control the one of the plurality of bit lines to allow or inhibit programming of the memory cells of the memory holes coupled to the one of the plurality of bit lines, the plurality of data latches each storing one bit to define bit combinations, and wherein the control means is further configured to:
operate and update the plurality of data latches based on the data being programmed to the memory cells and the threshold voltage of the memory cells and which of the plurality of data states is being programmed and verified during the program operation; and
update the plurality of data latches to track a quantity of subsequent ones of the plurality of program loops for each of the memory cells targeted to be programmed to the highest data state using one or more of the bit combinations.

3. The memory apparatus as set forth in claim 2, wherein each of the memory cells is configured to store three bits and the plurality of data states includes, in order of the threshold voltage increasing in magnitude, an erased data state and a first data state and a second data state and a third data state and a fourth data state and a fifth data state and a sixth data state and a seventh data state, the highest data state being the seventh data state, the plurality of data latches includes a first data latch and a second data latch and a third data latch each configured to store the data to be programmed during the program operation, the plurality of data latches includes a fourth data latch configured to control the one of the plurality of bit lines to allow or inhibit programming of the memory cells of the memory holes coupled to the one of the plurality of bit lines, the bit combinations include sixteen bit combinations, and the control means is further configured to:
update at least one of the first data latch and the second data latch and the third data latch and the fourth data latch associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state;
update at least one of the first data latch and the second data latch and the third data latch and the fourth data latch associated with the one of the memory cells targeted for the seventh data state from the first unused one of the sixteen bit combinations to a second unused one of the sixteen bit combinations following application of a first subsequent one of the series of programming pulses of the program voltage to the one of the memory cells targeted for the seventh data state; and
update at least one of the first data latch and the second data latch and the third data latch and the fourth data latch associated with the one of the memory cells targeted for the seventh data state from the second unused one of the sixteen bit combinations to one of the sixteen bit combinations associated with the erased data state to inhibit programming of the one of the memory cells targeted for the seventh data state following application of a second subsequent one of the series of programming pulses of the program voltage to the one of the memory cells targeted for the seventh data state.

4. The memory apparatus as set forth in claim 1, wherein the plurality of data states includes, in order of the threshold voltage increasing in magnitude, an erased data state, a next highest data state, and the highest data state, and the control means is further configured to:
prior to the next highest data state completing verification, program and verify ones of the memory cells using the series of programming pulses of the program voltage followed by the verification pulses of the plurality of program verify voltages associated therewith and lockout the memory cells having the threshold voltage greater than one of the plurality of verify voltages of the one of the plurality of data states targeted from further programming;
following the next highest data state completing verification, stop further verification of the ones of the memory cells targeted for the highest data state and count subsequent ones of the plurality of program loops; and
inhibit programming of the ones of the memory cells targeted for the highest data state in response to a quantity of the subsequent ones of the plurality of program loops exceeding a predetermined slow cell count threshold.

5. The memory apparatus as set forth in claim 4, wherein each of the memory cells is configured to store three bits and the plurality of data states includes, in order of the threshold voltage increasing in magnitude, the erased data state and a first data state and a second data state and a third data state and a fourth data state and a fifth data state and a sixth data state and a seventh data state, the next highest data state is the sixth data state and the highest data state is the seventh data state, and the control means is further configured to:
prior to the sixth data state completing verification, program and verify ones of the memory cells targeted for the first data state and the second data state and the third data state and the fourth data state and the fifth data state and the sixth data state and the seventh data state using the series of programming pulses of the program voltage followed by the verification pulses of the plurality of program verify voltages associated therewith and lockout the memory cells having the threshold voltage greater than one of the plurality of verify voltages of the one of the plurality of data states targeted from further programming in response to the ones of the memory cells targeted for the sixth data state and the seventh data state not having the threshold voltage greater than the one of the plurality of verify voltages associated with the sixth data state;
following the next highest data state completing verification, stop further verification of the ones of the memory cells targeted for the seventh data state and count subsequent ones of the plurality of program loops in response to the ones of the memory cells targeted for the sixth data state and the seventh data state having the threshold voltage greater than the one of the plurality of verify voltages associated with the sixth data state; and
inhibit programming of the ones of the memory cells targeted for the seventh data state in response to a quantity of the subsequent ones of the plurality of program loops exceeding the predetermined slow cell count threshold.

6. The memory apparatus as set forth in claim 1, wherein the memory cells are disposed in memory holes each coupled to one of a plurality of bit lines, the memory apparatus further includes a plurality of data latches each configured to store data to be programmed during the program operation and control the one of the plurality of bit lines to allow or inhibit programming of the memory cells of the memory holes coupled to the one of the plurality of bit lines, the plurality of data latches each storing one bit to define bit combinations, the plurality of data states includes, in order of the threshold voltage increasing in magnitude, an erased data state, a next highest data state, and the highest data state, and the control means is further configured to:
prior to the next highest data state completing verification, program and verify ones of the memory cells using the series of programming pulses of the program voltage followed by the verification pulses of the plurality of program verify voltages associated therewith and lockout the memory cells having the threshold voltage greater than one of the plurality of verify voltages of the one of the plurality of data states targeted from further programming; and
following the next highest data state completing verification, stop further verification of the ones of the memory cells targeted for the highest data state and update the plurality of data latches to track a quantity of subsequent ones of the plurality of program loops for each of the memory cells targeted to be programmed to the highest data state using one or more of the bit combinations.

7. The memory apparatus as set forth in claim 6, wherein each of the memory cells is configured to store three bits and the plurality of data states includes, in order of the threshold voltage increasing in magnitude, an erased data state and a first data state and a second data state and a third data state and a fourth data state and a fifth data state and a sixth data state and a seventh data state, the highest data state being the seventh data state, the plurality of data latches includes a first data latch and a second data latch and a third data latch each configured to store the data to be programmed during the program operation, the plurality of data latches includes a fourth data latch configured to control the one of the plurality of bit lines to allow or inhibit programming of the memory cells of the memory holes coupled to the one of the plurality of bit lines, the bit combinations include sixteen bit combinations, and the control means is further configured to:
prior to the sixth data state completing verification, update at least one of the first data latch and the second data latch and the third data latch and the fourth data latch associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state;
prior to the sixth data state completing verification, update at least one of the first data latch and the second data latch and the third data latch and the fourth data latch associated with the one of the memory cells targeted for the seventh data state to one of the sixteen bit combinations associated with the erased data state to inhibit programming of the one of the memory cells targeted for the seventh data state in response to the one of the memory cells having the threshold voltage greater than the one of the plurality of program verify voltages associated with the seventh data state sensed during one of the verification pulses of the one of the plurality of program verify voltages associated with the seventh data state;
prior to the sixth data state completing verification, update at least one of the first data latch and the second data latch and the third data latch and the fourth data latch associated with the one of the memory cells targeted for the seventh data state from the first unused one of the sixteen bit combinations to a second unused one of the sixteen bit combinations following application of one of the series of programming pulses of the program voltage to the one of the memory cells targeted for the seventh data state;
following the sixth data state completing verification, update at least one of the first data latch and the second data latch and the third data latch and the fourth data latch associated with the one of the memory cells targeted for the seventh data state from the first unused one of the sixteen bit combinations from the second unused one of the sixteen bit combinations to one of the sixteen bit combinations associated with the erased data state to inhibit programming of the one of the memory cells targeted for the seventh data state following application of a first subsequent one of the series of programming pulses of the program voltage to the one of the memory cells targeted for the seventh data state and in response to the one of the memory cells targeted for the seventh data state having the threshold voltage greater than the one of the plurality of verify voltages associated with the sixth data state and less than the one of the plurality of verify voltages associated with the seventh data state; and
following the sixth data state completing verification, update at least one of the first data latch and the second data latch and the third data latch and the fourth data latch associated with the one of the memory cells targeted for the seventh data state from the first unused one of the sixteen bit combinations to a second unused one of the sixteen bit combinations following application of a second subsequent one of the series of programming pulses of the program voltage to the one of the memory cells targeted for the seventh data state and in response to the one of the memory cells targeted for the seventh data state having the threshold voltage greater than the one of the plurality of verify voltages associated with the sixth data state and less than the one of the plurality of verify voltages associated with the seventh data state.

8. A controller in communication with a memory apparatus including memory cells each connected to one of a plurality of word lines and configured to retain a threshold voltage corresponding to one of a plurality of data states, the plurality of data states including a highest data state in which the threshold voltage of the memory cells associated therewith is higher than for others of the plurality of data states, the controller configured to:
instruct the memory apparatus to apply each of a series of programming pulses of a program voltage followed by verification pulses of a plurality of program verify voltages each associated with one of the plurality of data states to selected ones of the plurality of word lines to program and verify the memory cells connected thereto during each of a plurality of program loops of a program operation; and
instruct the memory apparatus to skip verification of the memory cells targeted for the highest data state in at least one of the plurality of program loops.

9. The controller as set forth in claim 8, wherein the memory cells are disposed in memory holes each coupled to one of a plurality of bit lines, the memory apparatus further includes a plurality of data latches each configured to store data to be programmed during the program operation and control the one of the plurality of bit lines to allow or inhibit programming of the memory cells of the memory holes coupled to the one of the plurality of bit lines, the plurality of data latches each storing one bit to define bit combinations, and wherein the controller is further configured to:
instruct the memory apparatus to operate and update the plurality of data latches based on the data being programmed to the memory cells and the threshold voltage of the memory cells and which of the plurality of data states is being programmed and verified during the program operation; and
instruct the memory apparatus to update the plurality of data latches to track a quantity of subsequent ones of the plurality of program loops for each of the memory cells targeted to be programmed to the highest data state using one or more of the bit combinations.

10. The controller as set forth in claim 9, wherein each of the memory cells is configured to store three bits and the plurality of data states includes, in order of the threshold voltage increasing in magnitude, an erased data state and a first data state and a second data state and a third data state and a fourth data state and a fifth data state and a sixth data state and a seventh data state, the highest data state being the seventh data state, the plurality of data latches includes a first data latch and a second data latch and a third data latch each configured to store the data to be programmed during the program operation, the plurality of data latches includes a fourth data latch configured to control the one of the plurality of bit lines to allow or inhibit programming of the memory cells of the memory holes coupled to the one of the plurality of bit lines, the bit combinations include sixteen bit combinations, and the controller is further configured to:
instruct the memory apparatus to update at least one of the first data latch and the second data latch and the third data latch and the fourth data latch associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state;
instruct the memory apparatus to update at least one of the first data latch and the second data latch and the third data latch and the fourth data latch associated with the one of the memory cells targeted for the seventh data state from the first unused one of the sixteen bit combinations to a second unused one of the sixteen bit combinations following application of a first subsequent one of the series of programming pulses of the program voltage to the one of the memory cells targeted for the seventh data state; and
instruct the memory apparatus to update at least one of the first data latch and the second data latch and the third data latch and the fourth data latch associated with the one of the memory cells targeted for the seventh data state from the second unused one of the sixteen bit combinations to one of the sixteen bit combinations associated with the erased data state to inhibit programming of the one of the memory cells targeted for the seventh data state following application of a second subsequent one of the series of programming pulses of the program voltage to the one of the memory cells targeted for the seventh data state.

11. The controller as set forth in claim 8, wherein the plurality of data states includes, in order of the threshold voltage increasing in magnitude, an erased data state, a next highest data state, and the highest data state, and the controller is further configured to:
prior to the next highest data state completing verification, instruct the memory apparatus to program and verify ones of the memory cells using the series of programming pulses of the program voltage followed by the verification pulses of the plurality of program verify voltages associated therewith and lockout the memory cells having the threshold voltage greater than one of the plurality of verify voltages of the one of the plurality of data states targeted from further programming;
following the next highest data state completing verification, instruct the memory apparatus to stop further verification of the ones of the memory cells targeted for the highest data state and count subsequent ones of the plurality of program loops; and
inhibit programming of the ones of the memory cells targeted for the highest data state in response to a quantity of the subsequent ones of the plurality of program loops exceeding a predetermined slow cell count threshold.

12. The controller as set forth in claim 11, wherein each of the memory cells is configured to store three bits and the plurality of data states includes, in order of the threshold voltage increasing in magnitude, the erased data state and a first data state and a second data state and a third data state and a fourth data state and a fifth data state and a sixth data state and a seventh data state, the next highest data state is the sixth data state and the highest data state is the seventh data state, and the controller is further configured to:
prior to the sixth data state completing verification, instruct the memory apparatus to program and verify ones of the memory cells targeted for the first data state and the second data state and the third data state and the fourth data state and the fifth data state and the sixth data state and the seventh data state using the series of programming pulses of the program voltage followed by the verification pulses of the plurality of program verify voltages associated therewith and lockout the memory cells having the threshold voltage greater than one of the plurality of verify voltages of the one of the plurality of data states targeted from further programming in response to the ones of the memory cells targeted for the sixth data state and the seventh data state not having the threshold voltage greater than the one of the plurality of verify voltages associated with the sixth data state;
following the next highest data state completing verification, instruct the memory apparatus to stop further verification of the ones of the memory cells targeted for the seventh data state and count subsequent ones of the plurality of program loops in response to the ones of the memory cells targeted for the sixth data state and the seventh data state having the threshold voltage greater than the one of the plurality of verify voltages associated with the sixth data state; and
instruct the memory apparatus to inhibit programming of the ones of the memory cells targeted for the seventh data state in response to a quantity of the subsequent ones of the plurality of program loops exceeding the predetermined slow cell count threshold.

13. The controller as set forth in claim 8, wherein the memory cells are disposed in memory holes each coupled to one of a plurality of bit lines, the memory apparatus further includes a plurality of data latches each configured to store data to be programmed during the program operation and control the one of the plurality of bit lines to allow or inhibit programming of the memory cells of the memory holes coupled to the one of the plurality of bit lines, the plurality of data latches each storing one bit to define bit combinations, the plurality of data states includes, in order of the threshold voltage increasing in magnitude, an erased data state, a next highest data state, and the highest data state, and the controller is further configured to:
prior to the next highest data state completing verification, instruct the memory apparatus to program and verify ones of the memory cells using the series of programming pulses of the program voltage followed by the verification pulses of the plurality of program verify voltages associated therewith and lockout the memory cells having the threshold voltage greater than one of the plurality of verify voltages of the one of the plurality of data states targeted from further programming; and
following the next highest data state completing verification, instruct the memory apparatus to stop further verification of the ones of the memory cells targeted for the highest data state and update the plurality of data latches to track a quantity of subsequent ones of the plurality of program loops for each of the memory cells targeted to be programmed to the highest data state using one or more of the bit combinations.

14. A method of operating a memory apparatus including memory cells each connected to one of a plurality of word lines and configured to retain a threshold voltage corresponding to one of a plurality of data states, the plurality of data states including a highest data state in which the threshold voltage of the memory cells associated therewith is higher than for others of the plurality of data states, the method comprising the steps of:
applying each of a series of programming pulses of a program voltage followed by verification pulses of a plurality of program verify voltages each associated with one of the plurality of data states to selected ones of the plurality of word lines to program and verify the memory cells connected thereto during each of a plurality of program loops of a program operation; and
skipping verification of the memory cells targeted for the highest data state in at least one of the plurality of program loops.

15. The method as set forth in claim 14, wherein the memory cells are disposed in memory holes each coupled to one of a plurality of bit lines, the memory apparatus further includes a plurality of data latches each configured to store data to be programmed during the program operation and control the one of the plurality of bit lines to allow or inhibit programming of the memory cells of the memory holes coupled to the one of the plurality of bit lines, the plurality of data latches each storing one bit to define bit combinations, and wherein the method further includes the steps of:
operating and updating the plurality of data latches based on the data being programmed to the memory cells and the threshold voltage of the memory cells and which of the plurality of data states is being programmed and verified during the program operation; and
updating the plurality of data latches to track a quantity of subsequent ones of the plurality of program loops for each of the memory cells targeted to be programmed to the highest data state using one or more of the bit combinations.

16. The method as set forth in claim 15, wherein each of the memory cells is configured to store three bits and the plurality of data states includes, in order of the threshold voltage increasing in magnitude, an erased data state and a first data state and a second data state and a third data state and a fourth data state and a fifth data state and a sixth data state and a seventh data state, the highest data state being the seventh data state, the plurality of data latches includes a first data latch and a second data latch and a third data latch each configured to store the data to be programmed during the program operation, the plurality of data latches includes a fourth data latch configured to control the one of the plurality of bit lines to allow or inhibit programming of the memory cells of the memory holes coupled to the one of the plurality of bit lines, the bit combinations include sixteen bit combinations, and the method further includes the steps of:
updating at least one of the first data latch and the second data latch and the third data latch and the fourth data latch associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state;
updating at least one of the first data latch and the second data latch and the third data latch and the fourth data latch associated with the one of the memory cells targeted for the seventh data state from the first unused one of the sixteen bit combinations to a second unused one of the sixteen bit combinations following application of a first subsequent one of the series of programming pulses of the program voltage to the one of the memory cells targeted for the seventh data state; and
updating at least one of the first data latch and the second data latch and the third data latch and the fourth data latch associated with the one of the memory cells targeted for the seventh data state from the second unused one of the sixteen bit combinations to one of the sixteen bit combinations associated with the erased data state to inhibit programming of the one of the memory cells targeted for the seventh data state following application of a second subsequent one of the series of programming pulses of the program voltage to the one of the memory cells targeted for the seventh data state.

17. The method as set forth in claim 14, wherein the plurality of data states includes, in order of the threshold voltage increasing in magnitude, an erased data state, a next highest data state, and the highest data state, and the method further includes the steps of:
prior to the next highest data state completing verification, programming and verifying ones of the memory cells using the series of programming pulses of the program voltage followed by the verification pulses of the plurality of program verify voltages associated therewith and locking out the memory cells having the threshold voltage greater than one of the plurality of verify voltages of the one of the plurality of data states targeted from further programming;
following the next highest data state completing verification, stopping further verification of the ones of the memory cells targeted for the highest data state and counting subsequent ones of the plurality of program loops; and
inhibiting programming of the ones of the memory cells targeted for the highest data state in response to a quantity of the subsequent ones of the plurality of program loops exceeding a predetermined slow cell count threshold.

18. The method as set forth in claim 17, wherein each of the memory cells is configured to store three bits and the plurality of data states includes, in order of the threshold voltage increasing in magnitude, the erased data state and a first data state and a second data state and a third data state and a fourth data state and a fifth data state and a sixth data state and a seventh data state, the next highest data state is the sixth data state and the highest data state is the seventh data state, and method further includes the steps of:
prior to the sixth data state completing verification, programming and verifying ones of the memory cells targeted for the first data state and the second data state and the third data state and the fourth data state and the fifth data state and the sixth data state and the seventh data state using the series of programming pulses of the program voltage followed by the verification pulses of the plurality of program verify voltages associated therewith and locking out the memory cells having the threshold voltage greater than one of the plurality of verify voltages of the one of the plurality of data states targeted from further programming in response to the ones of the memory cells targeted for the sixth data state and the seventh data state not having the threshold voltage greater than the one of the plurality of verify voltages associated with the sixth data state;
following the next highest data state completing verification, stopping further verification of the ones of the memory cells targeted for the seventh data state and counting subsequent ones of the plurality of program loops in response to the ones of the memory cells targeted for the sixth data state and the seventh data state having the threshold voltage greater than the one of the plurality of verify voltages associated with the sixth data state; and
inhibiting programming of the ones of the memory cells targeted for the seventh data state in response to a quantity of the subsequent ones of the plurality of program loops exceeding the predetermined slow cell count threshold.

19. The method as set forth in claim 14, wherein the memory cells are disposed in memory holes each coupled to one of a plurality of bit lines, the memory apparatus further includes a plurality of data latches each configured to store data to be programmed during the program operation and control the one of the plurality of bit lines to allow or inhibit programming of the memory cells of the memory holes coupled to the one of the plurality of bit lines, the plurality of data latches each storing one bit to define bit combinations, the plurality of data states includes, in order of the threshold voltage increasing in magnitude, an erased data state, a next highest data state, and the highest data state, and the method further includes the steps of:
prior to the next highest data state completing verification, programming and verifying ones of the memory cells using the series of programming pulses of the program voltage followed by the verification pulses of the plurality of program verify voltages associated therewith and locking out the memory cells having the threshold voltage greater than one of the plurality of verify voltages of the one of the plurality of data states targeted from further programming; and
following the next highest data state completing verification, stopping further verification of the ones of the memory cells targeted for the highest data state and updating the plurality of data latches to track a quantity of subsequent ones of the plurality of program loops for each of the memory cells targeted to be programmed to the highest data state using one or more of the bit combinations.

20. The method as set forth in claim 19, wherein each of the memory cells is configured to store three bits and the plurality of data states includes, in order of the threshold voltage increasing in magnitude, an erased data state and a first data state and a second data state and a third data state and a fourth data state and a fifth data state and a sixth data state and a seventh data state, the highest data state being the seventh data state, the plurality of data latches includes a first data latch and a second data latch and a third data latch each configured to store the data to be programmed during the program operation, the plurality of data latches includes a fourth data latch configured to control the one of the plurality of bit lines to allow or inhibit programming of the memory cells of the memory holes coupled to the one of the plurality of bit lines, the bit combinations include sixteen bit combinations, and the method further includes the steps of:
prior to the sixth data state completing verification, updating at least one of the first data latch and the second data latch and the third data latch and the fourth data latch associated with each one of the memory cells targeted for the seventh data state to a first unused one of the sixteen bit combinations in response to the one of the memory cells having the threshold voltage greater than the one of the plurality of program verify voltages associated with the sixth data state sensed during one of the verification pulses of the one of the plurality of program verify voltages associated with the sixth data state;
prior to the sixth data state completing verification, updating at least one of the first data latch and the second data latch and the third data latch and the fourth data latch associated with the one of the memory cells targeted for the seventh data state to one of the sixteen bit combinations associated with the erased data state to inhibit programming of the one of the memory cells targeted for the seventh data state in response to the one of the memory cells having the threshold voltage greater than the one of the plurality of program verify voltages associated with the seventh data state sensed during one of the verification pulses of the one of the plurality of program verify voltages associated with the seventh data state;
prior to the sixth data state completing verification, updating at least one of the first data latch and the second data latch and the third data latch and the fourth data latch associated with the one of the memory cells targeted for the seventh data state from the first unused one of the sixteen bit combinations to a second unused one of the sixteen bit combinations following application of one of the series of programming pulses of the program voltage to the one of the memory cells targeted for the seventh data state;
following the sixth data state completing verification, updating at least one of the first data latch and the second data latch and the third data latch and the fourth data latch associated with the one of the memory cells targeted for the seventh data state from the first unused one of the sixteen bit combinations from the second unused one of the sixteen bit combinations to one of the sixteen bit combinations associated with the erased data state to inhibit programming of the one of the memory cells targeted for the seventh data state following application of a first subsequent one of the series of programming pulses of the program voltage to the one of the memory cells targeted for the seventh data state and in response to the one of the memory cells targeted for the seventh data state having the threshold voltage greater than the one of the plurality of verify voltages associated with the sixth data state and less than the one of the plurality of verify voltages associated with the seventh data state; and
following the sixth data state completing verification, updating at least one of the first data latch and the second data latch and the third data latch and the fourth data latch associated with the one of the memory cells targeted for the seventh data state from the first unused one of the sixteen bit combinations to a second unused one of the sixteen bit combinations following application of a second subsequent one of the series of programming pulses of the program voltage to the one of the memory cells targeted for the seventh data state and in response to the one of the memory cells targeted for the seventh data state having the threshold voltage greater than the one of the plurality of verify voltages associated with the sixth data state and less than the one of the plurality of verify voltages associated with the seventh data state.
